(19) United States
(12) Patent Application Publication
(10) Pub. No.: US 2026/0245516 A1
(43) Pub. Date: Aug. 20, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Seung Jun LEE, Yongin-si (KR); Jae Woo LEE, Yongin-si (KR); Tae Ho KIM, Yongin-si (KR); Dong Min LEE, Yongin-si (KR)

(21) Appl. No.: 19/322,967

(22) Filed: Sep. 9, 2025

(30) Foreign Application Priority Data
Feb. 19, 2025 (KR) 10-2025-0021555

(51) Int. Cl. G09G 3/3233

(52) U.S. Cl. CPC G09G 3/3233; G09G 2300/0426; G09G 2300/0819; G09G 2320/0257

(57) ABSTRACT

A display device comprises a substrate having a display area including a plurality of emission areas arranged therein. A circuit layer is located on the substrate. An element layer is located on the circuit layer. The element layer comprises light emitting elements arranged in each of the plurality of emission areas. The circuit layer comprises light emitting pixel drivers electrically connected to the light emitting elements. An initialization voltage line transmits an initialization voltage. The light emitting pixel drivers comprise first light emitting pixel drivers, second light emitting pixel drivers and third light emitting pixel drivers. The initialization voltage line comprises a first initialization voltage line transmitting a first initialization voltage to the third light emitting pixel drivers and a second initialization voltage line transmitting a second initialization voltage having a different voltage level from the first initialization voltage to the second light emitting pixel drivers.

### CROSS-REFERENCE TO RELATED APPLICATION

This application claims priority under 35 U.S.C. 119 to Korean Patent Application No. 10-2025-0021555, filed on Feb. 19, 2025 in the Korean Intellectual Property Office, the disclosure of which is incorporated by reference in its entirety herein.

### 1. Technical Field

The present disclosure relates to a display device.

### 2. Discussion of Related Art

The demands on display devices for displaying images in various ways have increased along with the advancement of the information society. For example, display devices are applied in an increasing number of electronic devices, such as smartphones, digital cameras, laptop computers, navigation devices, and smart televisions.

The display device may be various types including a flat panel display device, such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer containing an organic light emitting material. As described above, the organic light emitting display device implements image display using a self-light emitting element. Therefore, the organic light emitting display device may have relatively superior performance in power consumption, response speed, luminous efficiency, luminance, and wide viewing angle compared to other display devices.

One surface of the display device may be a display surface including a display area in which an image is displayed and a non-display area that is positioned along a periphery of the display area. Emission areas emitting light with respective luminances and colors may be arranged in the display area.

### SUMMARY

The display device may include light emitting elements located in the emission areas.

Since each of the light emitting elements includes a structure in which a light emitting layer containing an organic light emitting material is located between an anode electrode and a cathode electrode, it may have a parasitic capacitance.

If a voltage charged to the parasitic capacitance of the light emitting elements during the previous image frame remains, the luminance of each image frame may not be properly displayed, which may result in display defects such as luminance reduction and afterimages.

In an embodiment, each image frame may include an initialization period for removing the voltage charged to the parasitic capacitance of each of the light emitting elements. For example, during the initialization period, the light emitting elements may be initialized to an initialization voltage.

The parasitic capacitance of the light emitting elements may vary depending on the organic light emitting material and the width of the light emitting layer. Accordingly, when the light emitting elements of the display area are initialized to the same voltage level, some of the light emitting elements may be properly initialized, whereas some others may not be properly initialized, which may result in display defects such as partial afterimages and stains.

In an embodiment, some of the light emitting elements may be initialized to a first initialization voltage, and some others may be initialized to a second initialization voltage having a different voltage level from the first initialization voltage. In this case, since both a first initialization voltage line for transmitting the first initialization voltage and a second initialization voltage line for transmitting the second initialization voltage need to be placed in the display area, the resolution may be degraded.

In view of the foregoing, aspects of the present disclosure provide a display device which includes a first initialization voltage line and a second initialization voltage line and is advantageous for increasing resolution, and an electronic device including the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, a display device includes a substrate having a display area including a plurality of emission areas arranged therein and a non-display area located around the display area. A circuit layer is located on the substrate. An element layer is located on the circuit layer. The element layer comprises light emitting elements arranged in each of the plurality of emission areas. The circuit layer comprises light emitting pixel drivers electrically connected to the light emitting elements and arranged in a first direction and a second direction intersecting the first direction. An initialization voltage line transmits an initialization voltage to the light emitting pixel drivers. The plurality of emission areas comprises first emission areas, second emission areas, and third emission areas that emit light of different wavelength bands from each other. The light emitting pixel drivers comprise first light emitting pixel drivers electrically connected to the light emitting elements of the first emission areas. Second light emitting pixel drivers are electrically connected to the light emitting elements of the second emission areas. Third light emitting pixel drivers are electrically connected to the light emitting elements of the third emission areas. The initialization voltage line comprises a first initialization voltage line transmitting a first initialization voltage to the third light emitting pixel drivers. A second initialization voltage line transmits a second initialization voltage having a different voltage level from the first initialization voltage to the second light emitting pixel drivers.

In an embodiment, the circuit layer comprises a first semiconductor layer located on the substrate; a first gate insulating layer covering the first semiconductor layer; a first gate conductive layer located on the first gate insulating layer; a second gate insulating layer covering the first gate conductive layer; a second gate conductive layer located on the second gate insulating layer; a first interlayer insulating layer covering the second gate conductive layer; a second semiconductor layer located on the first interlayer insulating layer; a third gate insulating layer covering the second semiconductor layer; a third gate conductive layer located on the third gate insulating layer; a second interlayer insulating layer covering the third gate conductive layer; and a first source-drain conductive layer located on the second interlayer insulating layer. The first initialization voltage line comprises a first initialization voltage main line located in the second gate conductive layer and extending in the first direction. The second initialization voltage line comprises a second initialization voltage main line located in the first source-drain conductive layer and extending in the first direction.

In an embodiment, the circuit layer further comprises a bias control line transmitting a bias control signal to the light emitting pixel drivers. The bias control line extends in the first direction and is located in the third gate conductive layer. The first initialization voltage main line, the second initialization voltage main line, and the bias control line are located adjacent to each other in the second direction, and located adjacent to a boundary between two light emitting pixel drivers adjacent to each other in the second direction.

In an embodiment, the first light emitting pixel drivers are electrically connected to the first initialization voltage line. One first light emitting pixel driver and one third light emitting pixel driver adjacent to each other in the second direction are electrically connected to one first initialization voltage main line and one bias control line located adjacent to a boundary between the one first light emitting pixel driver and the one third light emitting pixel driver. Two second light emitting pixel drivers adjacent to the one first light emitting pixel driver and the one third light emitting pixel driver in the first direction and adjacent to each other in the second direction are electrically connected to one second initialization voltage main line and the one bias control line located adjacent to a boundary between the two second light emitting pixel drivers.

In an embodiment, the first light emitting pixel drivers are electrically connected to the second initialization voltage line. Two second light emitting pixel drivers adjacent to each other in the second direction and one first light emitting pixel driver adjacent to one of the two second light emitting pixel drivers in the first direction are electrically connected to one second initialization voltage main line and one bias control line located adjacent to a boundary between the two second light emitting pixel drivers. One third light emitting pixel driver adjacent to the other one of the two second light emitting pixel drivers in the first direction and adjacent to the one first light emitting pixel driver in the second direction is electrically connected to one first initialization voltage main line and the one bias control line located adjacent to a boundary between the one first light emitting pixel driver and the one third light emitting pixel driver.

In an embodiment, t4he first initialization voltage main line is located adjacent to the bias control line on a first side in the second direction. The second initialization voltage line is located adjacent to the bias control line on an opposite second side in the second direction.

In an embodiment, the first initialization voltage main line, the second initialization voltage main line, and the bias control line overlap each other in a third direction that is a thickness direction of the substrate intersecting the first and second directions.

In an embodiment, each of the light emitting pixel drivers comprises a first transistor; a second transistor electrically connected between a data line transmitting a data signal and a gate electrode of the first transistor; a third transistor electrically connected between a reference voltage line transmitting a reference voltage and the gate electrode of the first transistor; a fourth transistor electrically connected between one of the light emitting elements and the initialization voltage line; a fifth transistor electrically connected between a first power line transmitting a first power and a first electrode of the first transistor; a sixth transistor electrically connected between the one light emitting element and a second electrode of the first transistor; a first capacitor electrically connected between the gate electrode of the first transistor and the second electrode of the first transistor; and a second capacitor electrically connected between the first power line and the second electrode of the first transistor. Each of the first transistor, the second transistor, the third transistor, the fourth transistor, the fifth transistor, and the sixth transistor comprises a gate electrode, a channel portion overlapping the gate electrode, a first electrode portion connected to a first side of the channel portion, and a second electrode portion connected to an opposite second side of the channel portion. The channel portion, the first electrode portion and the second electrode portion of each of the first transistor, the second transistor, the third transistor and the fourth transistor are located in the second semiconductor layer. The channel portion, the first electrode portion and the second electrode portion of each of the fifth transistor and the sixth transistor are located in the first semiconductor layer. The gate electrode of the fourth transistor is electrically connected to the bias control line.

In an embodiment, the circuit layer further comprises a first planarization layer covering the first source-drain conductive layer; a second source-drain conductive layer located on the first planarization layer; and a second planarization layer covering the second source-drain conductive layer. The data line extends in the second direction and is located in the second source-drain conductive layer. The first initialization voltage line further comprises a first initialization voltage sub-line located in the second source-drain conductive layer, extending in the second direction and electrically connected to the first initialization voltage main line. The second initialization voltage line further comprises a second initialization voltage sub-line located in the second source-drain conductive layer, extending in the second direction and electrically connected to the second initialization voltage main line. The reference voltage line comprises a reference voltage main line located in the second gate conductive layer, extending in the first direction and spaced apart from the bias control line in the second direction; and a reference voltage sub-line located in the second source-drain conductive layer, extending in the second direction and electrically connected to the reference voltage main line. The first power line comprises a power main line located in the first gate conductive layer and extending in the first direction; and a power sub-line located in the second source-drain conductive layer, extending in the second direction and electrically connected to the power main line. One of the two light emitting pixel drivers is located adjacent to the reference voltage main line on a first side in the second direction. The other of the two light emitting pixel drivers is located adjacent to the reference voltage main line on an opposite second side in the second direction.

In an embodiment, each of the power main line, the reference voltage sub-line, the first initialization voltage sub-line and the second initialization voltage sub-line is located adjacent to a boundary between two light emitting pixel drivers adjacent to each other in the first direction. The power main line is arranged alternately with the reference voltage sub-line, the first initialization voltage sub-line, and the second initialization voltage sub-line. The reference voltage sub-line is arranged alternately with the first initialization voltage sub-line and the second initialization voltage sub-line. The first initialization voltage sub-line and the second initialization voltage sub-line are arranged alternately with each other.

In an embodiment, the display device further comprises a display driving circuit transmitting data signals of the light emitting pixel drivers. The circuit layer further comprises data lines located in the display area and transmitting the data signals to the light emitting pixel drivers; data supply lines located in the non-display area and electrically connected between each of the data lines and the display driving circuit; first auxiliary lines located in the display area and extending in the first direction; and second auxiliary lines located in the display area, extending in the second direction and adjacent to the data lines. A bypass area of the display area comprises a bypass middle area, a first bypass side area parallel to the bypass middle area in the first direction and in direct contact with the non-display area, and a second bypass side area located between the bypass middle area and the first bypass side area in the first direction. The data supply lines extend to the bypass middle area and the second bypass side area. The data lines comprise a first data line located in the first bypass side area, and a second data line located in the second bypass side area. The data lines and the second auxiliary lines are located on an insulating layer covering the first auxiliary lines. The first auxiliary lines comprise a first bypass auxiliary line electrically connected to the first data line. The second auxiliary lines comprise a second bypass auxiliary line adjacent to the second data line and electrically connected to the first bypass auxiliary line. The data supply lines comprise a first data supply line transmitting a data signal of the first data line, and a second data supply line transmitting a data signal of the second data line. The first data supply line is electrically connected to the first data line through the second bypass auxiliary line and the first bypass auxiliary line. The second data supply line is electrically connected directly to the second data line.

In an embodiment, the first emission areas emit light of a first wavelength band. The second emission areas emit light of a second wavelength band lower than the first wavelength band. The third emission areas emit light of a third wavelength band lower than the second wavelength band.

According to an embodiment of the present disclosure, an electronic device comprises a display device displaying an image; a memory storing an application; a processor executing the application and transmitting an image data signal and an input control signal to the display device; and a power module transmitting a power to the display device. The display device comprises a substrate comprising a display area including a plurality of emission areas arranged therein and a non-display area located around the display area; a circuit layer located on the substrate; and an element layer located on the circuit layer. The element layer comprises light emitting elements arranged in each of the plurality of emission areas. The circuit layer comprises light emitting pixel drivers electrically connected to the light emitting elements and arranged in a first direction and a second direction intersecting the first direction; and an initialization voltage line transmitting an initialization voltage to the light emitting pixel drivers. The initialization voltage line comprises a first initialization voltage line transmitting a first initialization voltage to a first portion of the light emitting pixel drivers; and a second initialization voltage line transmitting a second initialization voltage having a different voltage level from the first initialization voltage to a second portion of the light emitting pixel drivers not including the first portion. Each of the light emitting pixel drivers comprises a first transistor; a second transistor electrically connected between a data line transmitting a data signal and a gate electrode of the first transistor; a third transistor electrically connected between a reference voltage line transmitting a reference voltage and the gate electrode of the first transistor; a fourth transistor electrically connected between one of the light emitting elements and the initialization voltage line; a fifth transistor electrically connected between a first power line transmitting a first power and a first electrode of the first transistor; a sixth transistor electrically connected between the one light emitting element and a second electrode of the first transistor; a first capacitor electrically connected between the gate electrode of the first transistor and the second electrode of the first transistor; and a second capacitor electrically connected between the first power line and the second electrode of the first transistor.

In an embodiment, the plurality of emission areas comprise first emission areas emitting light of a first wavelength band; second emission areas emitting light of a second wavelength band lower than the first wavelength band; and third emission areas emitting light of a third wavelength band lower than the second wavelength band. The light emitting pixel drivers comprise first light emitting pixel drivers electrically connected to the light emitting elements of the first emission areas; second light emitting pixel drivers electrically connected to the light emitting elements of the second emission areas; and third light emitting pixel drivers electrically connected to the light emitting elements of the third emission areas. The second light emitting pixel drivers are electrically connected to the second initialization voltage line. The third light emitting pixel drivers are electrically connected to the first initialization voltage line.

In an embodiment, the circuit layer comprises a first semiconductor layer located on the substrate; a first gate insulating layer covering the first semiconductor layer; a first gate conductive layer located on the first gate insulating layer; a second gate insulating layer covering the first gate conductive layer; a second gate conductive layer located on the second gate insulating layer; a first interlayer insulating layer covering the second gate conductive layer; a second semiconductor layer located on the first interlayer insulating layer; a third gate insulating layer covering the second semiconductor layer; a third gate conductive layer located on the third gate insulating layer; a second interlayer insulating layer covering the third gate conductive layer; and a first source-drain conductive layer located on the second interlayer insulating layer. Each of the first transistor, the second transistor, the third transistor, the fourth transistor, the fifth transistor, and the sixth transistor comprises a gate electrode, a channel portion overlapping the gate electrode, a first electrode portion connected to a first side of the channel portion, and a second electrode portion connected to an opposite second side of the channel portion. The channel portion, the first electrode portion and the second electrode portion of each of the first transistor, the second transistor, the third transistor and the fourth transistor are located in the second semiconductor layer. The channel portion, the first electrode portion and the second electrode portion of each of the fifth transistor and the sixth transistor are located in the first semiconductor layer. The gate electrode of the fourth transistor is electrically connected to a bias control line transmitting a bias control signal.

In an embodiment, the bias control line extends in the first direction and is located in the third gate conductive layer. The first initialization voltage line comprises a first initialization voltage main line located in the second gate conductive layer and extending in the first direction. The second initialization voltage line comprises a second initialization voltage main line located in the first source-drain conductive layer and extending in the first direction. The first initialization voltage main line, the second initialization voltage main line, and the bias control line are located adjacent to each other in the second direction, and located adjacent to a boundary between two light emitting pixel drivers adjacent to each other in the second direction.

In an embodiment, the first light emitting pixel drivers are electrically connected to the first initialization voltage line. One first light emitting pixel driver and one third light emitting pixel driver adjacent to each other in the second direction are electrically connected to one first initialization voltage main line and one bias control line located adjacent to a boundary between the one first light emitting pixel driver and the one third light emitting pixel driver. Two second light emitting pixel drivers adjacent to the one first light emitting pixel driver and the one third light emitting pixel driver in the first direction and adjacent to each other in the second direction are electrically connected to one second initialization voltage main line and the one bias control line located adjacent to a boundary between the two second light emitting pixel drivers.

In an embodiment, the first light emitting pixel drivers are electrically connected to the second initialization voltage line. Two second light emitting pixel drivers adjacent to each other in the second direction and one first light emitting pixel driver adjacent to one of the two second light emitting pixel drivers in the first direction are electrically connected to one second initialization voltage main line and one bias control line located adjacent to a boundary between the two second light emitting pixel drivers. One third light emitting pixel driver adjacent to the other one of the two second light emitting pixel drivers in the first direction and adjacent to the one first light emitting pixel driver in the second direction is electrically connected to one first initialization voltage main line and the one bias control line located adjacent to a boundary between the one first light emitting pixel driver and the one third light emitting pixel driver.

In an embodiment, the first initialization voltage main line is located adjacent to the bias control line on a first side in the second direction. The second initialization voltage line is located adjacent to the bias control line on an opposite second side in the second direction.

In an embodiment, the first initialization voltage main line, the second initialization voltage main line, and the bias control line overlap each other in a third direction that is a thickness direction of the substrate.

The display device according to an embodiment includes a substrate, a circuit layer located on the substrate, and an element layer located on the circuit layer.

The substrate includes a display area where emission areas are arranged, and a non-display area located around the display area.

The element layer includes light emitting elements respectively located in to the emission areas.

The circuit layer includes light emitting pixel drivers electrically connected to the light emitting elements and arranged in a first direction and a second direction, and an initialization voltage line transmitting an initialization voltage to the light emitting pixel drivers.

The initialization voltage line includes a first initialization voltage line transmitting a first initialization voltage to some of the light emitting pixel drivers, and a second initialization voltage line transmitting a second initialization voltage to some others of the light emitting pixel drivers.

According to an embodiment, the emission areas may include first emission areas emitting light of a first wavelength band, second emission areas emitting light of a second wavelength band, and third emission areas emitting light of a third wavelength band. The light emitting pixel drivers may include first light emitting pixel drivers electrically connected to the light emitting elements of the first emission areas, second light emitting pixel drivers electrically connected to the light emitting elements of the second emission areas, and third light emitting pixel drivers electrically connected to the light emitting elements of the third emission areas. The third light emitting pixel drivers may be electrically connected to the first initialization voltage line, the second light emitting pixel drivers may be electrically connected to the second initialization voltage line, and the first light emitting pixel drivers may be electrically connected to one of the first initialization voltage line and the second initialization voltage line.

In this way, some of the light emitting elements may be initialized to the first initialization voltage, and some others may be initialized to the second initialization voltage. Therefore, display defects such as partial afterimages and stains may be reduced, so that the display quality of the display device may be improved.

According to an embodiment, the circuit layer may include a first semiconductor layer, a first gate conductive layer, a second gate conductive layer, a second semiconductor layer, a third gate conductive layer, and a first source-drain conductive layer that are stacked in a third direction and mutually insulated.

According to an embodiment, the circuit layer may further include a bias control line transmitting a bias control signal to the light emitting pixel drivers.

The first initialization voltage line may include a first initialization voltage main line located in the second gate conductive layer and extending in the first direction.

The second initialization voltage line may include a second initialization voltage main line located in the first source-drain conductive layer and extending in the first direction.

The bias control line may be located in the third gate conductive layer.

According to an embodiment, the first initialization voltage main line, the second initialization voltage main line, and the bias control line may be located adjacent to each other in the second direction, and located adjacent to a boundary between two light emitting pixel drivers adjacent to each other in the second direction.

For example, two second light emitting pixel drivers adjacent to each other in the second direction may be electrically connected to one second initialization voltage main line and one bias control line arranged between the two second light emitting pixel drivers.

When the first light emitting pixel drivers are electrically connected to the first initialization voltage line, one first light emitting pixel driver and one third light emitting pixel driver, which are adjacent to each other in the second direction and adjacent to the two second light emitting pixel drivers in the first direction, may be electrically connected to one first initialization voltage main line and one bias control line that are arranged between the first light emitting pixel driver and the third light emitting pixel driver.

Alternatively, when the first light emitting pixel drivers are electrically connected to the first initialization voltage line, one first light emitting pixel driver may be electrically connected to one second initialization voltage main line, and one third light emitting pixel driver may be electrically connected to one first initialization voltage main line.

One first initialization voltage main line, one second initialization voltage main line, and one bias control line may be arranged adjacent to a boundary between one first light emitting pixel driver and one third light emitting pixel driver and a boundary between two second light emitting pixel drivers.

In this way, while the first initialization voltage and the second initialization voltage for improving the display quality may be transmitted to the display area, the number of the first initialization voltage main lines for transmitting the first initialization voltage and the number of the second initialization voltage main lines for transmitting the second initialization voltage may each be reduced to half the number of pixel columns. Here, each of the pixel columns includes light emitting pixel drivers arranged side by side in the second direction.

In other words, when 2n (here, n denotes a natural number) pixel columns are arranged in the display area, the first initialization voltage and the second initialization voltage may be transmitted to the display area through n first initialization voltage main lines and n second initialization voltage main lines, which are half the number of the pixel columns.

Therefore, the width occupied by the first initialization voltage main lines for transmitting the first initialization voltage and the second initialization voltage main lines for transmitting the second initialization voltage in the display area may be reduced, which may be advantageous for increasing the resolution of the display device.

Likewise, the number of the bias control lines may also be reduced to half the number of the pixel columns, which may be advantageous for increasing the resolution of the display device.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a perspective view showing an electronic device according to an embodiment of the present disclosure;

FIG. 2 is an exploded perspective view of the electronic device shown in FIG. 1 according to an embodiment of the present disclosure;

FIG. 3 is a plan view illustrating the display device of FIG. 2 according to an embodiment of the present disclosure;

FIG. 4 is a cross-sectional view taken along line A-A′ of FIG. 3 according to an embodiment of the present disclosure;

FIG. 5 is a schematic diagram showing part B of FIG. 3 according to an embodiment of the present disclosure;

FIG. 6 is an equivalent circuit diagram showing the third light emitting pixel driver of FIG. 5 according to an embodiment of the present disclosure;

FIG. 7 is an equivalent circuit diagram showing the second light emitting pixel driver of FIG. 5 according to an embodiment of the present disclosure;

FIG. 8 is a cross-sectional view showing the first transistor, the second transistor, the sixth transistor, the first and second capacitors, and the light emitting element of FIGS. 6 and 7 according to an embodiment of the present disclosure;

FIG. 9 is a schematic view showing the substrate of FIG. 4 according to an embodiment of the present disclosure;

FIG. 10 is a schematic diagram showing part C of FIG. 9 according to an embodiment of the present disclosure;

FIG. 11 is a schematic diagram showing part D of FIG. 9 according to an embodiment of the present disclosure;

FIG. 12 is a cross-sectional view taken along line E-E′ of FIG. 10 according to an embodiment of the present disclosure;

FIGS. 13, 14, 15, and 16 are plan views showing four light emitting pixel drivers adjacent to each other in a 2×2 matrix form among the light emitting pixel drivers of FIG. 5 according to embodiments of the present disclosure;

FIG. 17 is a plan view showing a first power line, a reference voltage line, and an initialization voltage line according to an embodiment of the present disclosure ;

FIG. 18 is a cross-sectional view taken along line F-F′ of FIG. 17 according to an embodiment of the present disclosure;

FIGS. 19 and 20 are plan views showing a first initialization voltage main line, a bias control line, and a second initialization voltage main line according to embodiments of the present disclosure;

FIG. 21 is a cross-sectional view taken along line G-G′ of FIG. 20 according to an embodiment of the present disclosure.

FIG. 22 is a block diagram of an electronic device according to an embodiment of the present disclosure; and

FIG. 23 is schematic views of electronic devices according to various embodiments of the present disclosure.

### DETAILED DESCRIPTION OF EMBODIMENTS

Non-limiting embodiments of the present disclosure will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “spaced apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, non-limiting embodiments of the present disclosure will be described with reference to the accompanying drawings.

A display device includes a first initialization voltage line transmitting a first initialization voltage to a first portion of light emitting pixel drivers and a second initialization voltage line transmitting a second initialization voltage having a different voltage from the first initialization voltage to a second portion of the light emitting pixel drivers not including the first portion of the light emitting pixel drivers. Accordingly, display defects such as partial afterimages and stains may be reduced, and the display device may have increased display quality.

A width allocated to the arrangement of the reference voltage main line, the bias control line, the first initialization voltage main line, and the second initialization voltage main line in the display area may be reduced to provide a high resolution of the display device.

A bias control line may be located between the first initialization voltage main line and the second initialization voltage main line to reduce distortion of the bias control signal.

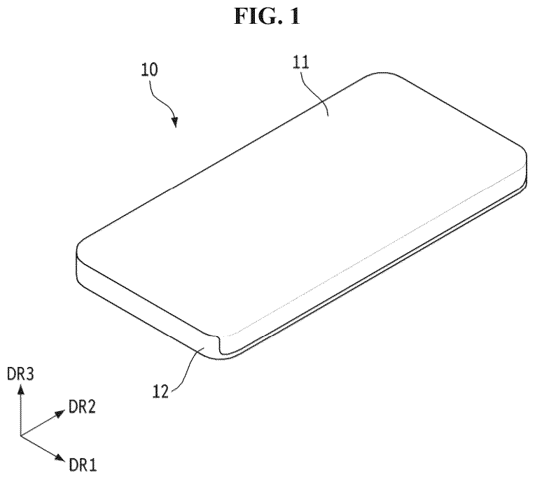

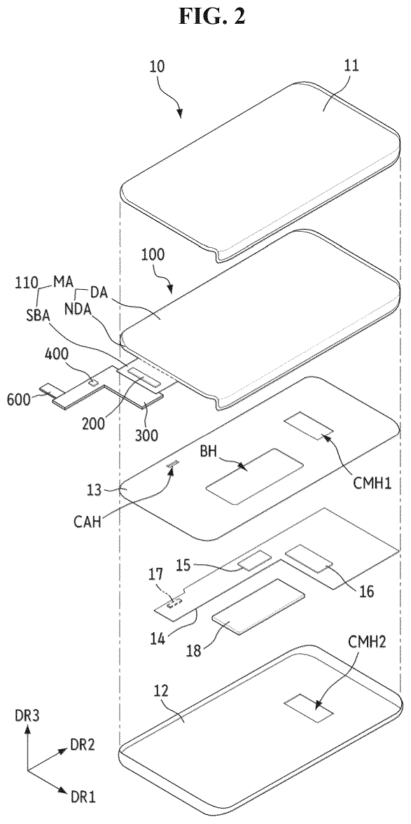

FIG. 1 is a perspective view showing an electronic device according to an embodiment. FIG. 2 is an exploded perspective view of the electronic device shown in FIG. 1.

Referring to FIG. 1, an electronic device 10 according to an embodiment is a device having a function of displaying an image in a display area. The electronic device 10 may provide increased portability. For example, in an embodiment the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 10 according to an embodiment is not necessarily limited to a portable electronic device, and may be various large-sized or medium-sized devices such as a television, a laptop computer, a monitor, a billboard, and an Internet-of-Things (IoT) device.

The electronic device 10 according to an embodiment may include a cover window 11 and a lower cover 12, which are provided as a housing to protect a display device 100 (see FIG. 2).

Referring to FIG. 2, in an embodiment the electronic device 10 may further include the display device 100, a bracket 13, and a main circuit board 14, which are accommodated between the cover window 11 and the lower cover 12.

The display device 100 may include a main region MA including a display area DA where an image is displayed and a non-display area NDA around the display area DA (e.g., in a plan view), and a sub-region SBA protruding from one side of the main region MA.

The display device 100 may further include a display driving circuit 200 located in the sub-region SBA, a display circuit board 300 bonded to one side of the sub-region SBA, a touch driving circuit 400 mounted on the display circuit board 300, and a cable 600 extending from one side of the display circuit board 300.

In the present specification, a first direction DR1 may be a direction parallel to a short side of the electronic device 10 in plan view, For example, a horizontal direction of the electronic device 10. A second direction DR2 may be a direction parallel to a long side of the electronic device 10 in plan view, For example, a vertical direction of the electronic device 10. A third direction DR3 may be a thickness direction of the electronic device 10. However, embodiments of the present disclosure are not necessarily limited thereto. Additionally, while the first to third directions DR1 to DR3 are shown as being perpendicular to each other, the first to third directions DR1 to DR3 may intersect each other at various different angles.

The electronic device 10 may have a shape similar to a rectangular shape in plan view. For example, the electronic device 10 may have a rectangular shape, in a plan view, having short sides in the first direction DR1 and long sides in the second direction DR2. A corner where the short side in the first direction DR1 and the long side in the second direction DR2 meet may be right-angled or rounded with a selected curvature. The planar shape of the electronic device 10 is not necessarily limited to the rectangular shape, and may be formed in another polygonal shape, a circular shape, an elliptical shape, an irregular shape, etc.

The cover window 11 may be located on the display device 100 to cover the top surface of the display device 100. The cover window 11 may serve to protect the top surface of the display device 100.

The cover window 11 may include a light transmitting portion that is transparent and a light blocking portion that is opaque.

The light transmitting portion may overlap the display area DA of the display device 100 in the third direction DR3, and the light blocking portion may overlap the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion.

In an embodiment, the light transmitting portion of the cover window 11 may be located on at least a majority of each of the top, left, and right surface portions of the cover window 11.

In an embodiment, the light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be located below the cover window 11.

For example, the cover window 11 may be located on the display device 100 (e.g., in the third direction DR3).

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

In an embodiment, the display device 100 may include the main region MA serving as a display surface and the sub-region SBA protruding from at least a part of one side of the main region MA, such as a lower side in the second direction DR2.

The main region MA may include the display area DA displaying an image and the non-display area NDA that is a peripheral area of the display area DA.

In an embodiment, the display area DA may be located in a majority of the main region MA. The display area DA may be located at the center of the main region MA.

For example, each of the top, left, and right surface portions of the display device 100 may include the display area DA and the non-display area NDA.

In an embodiment, the display area DA may be located on a majority of each of the top, left, and right surface portions of the display device 100.

The non-display area NDA may be located outside the display area DA (e.g., in a plan view). The non-display area NDA may be an edge area of the main region MA.

The non-display area NDA may be located at the upper edge and lower edge of the top surface portion of the display device 100, the upper edge, left edge, and lower edge of the left surface portion of the display device 100, and the upper edge, right edge, and lower edge of the right surface portion of the display device 100.

In an embodiment, the sub-region SBA may protrude from one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but is not necessarily limited thereto.

Since a part of the sub-region SBA is transformed to be bent, another part of the sub-region SBA may overlap the main region MA in the third direction DR3.

The display driving circuit 200 may be mounted on the sub-region SBA, and the display circuit board 300 may be attached to the sub-region SBA.

In an embodiment, one end of the display circuit board 300 may be attached to pads located at the lower edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

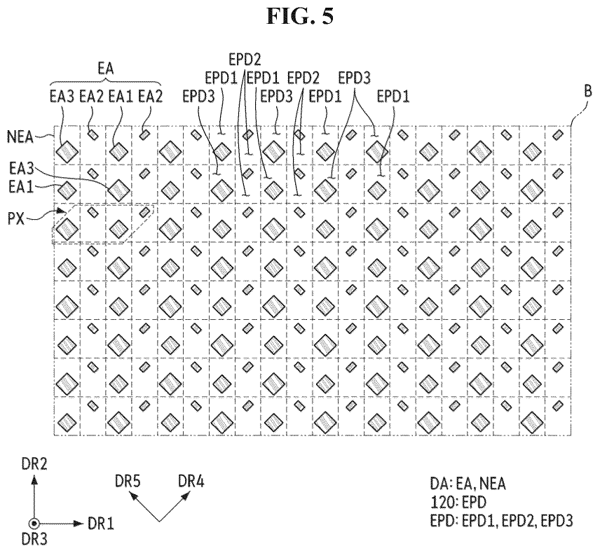

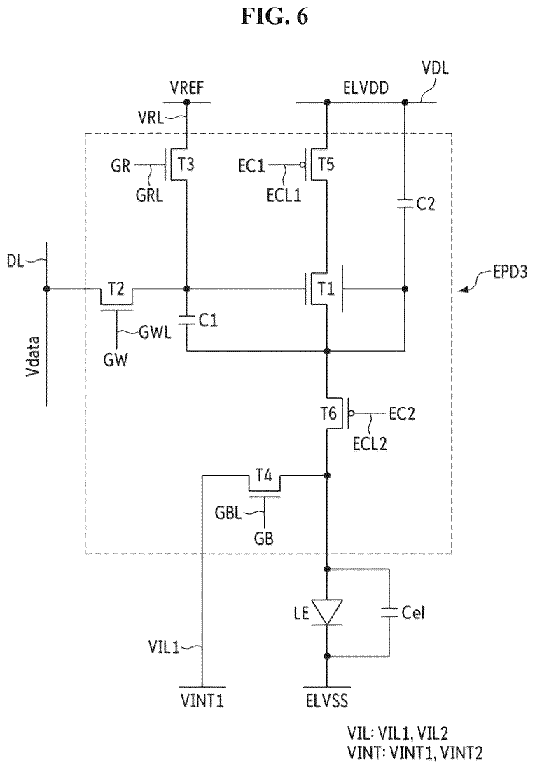

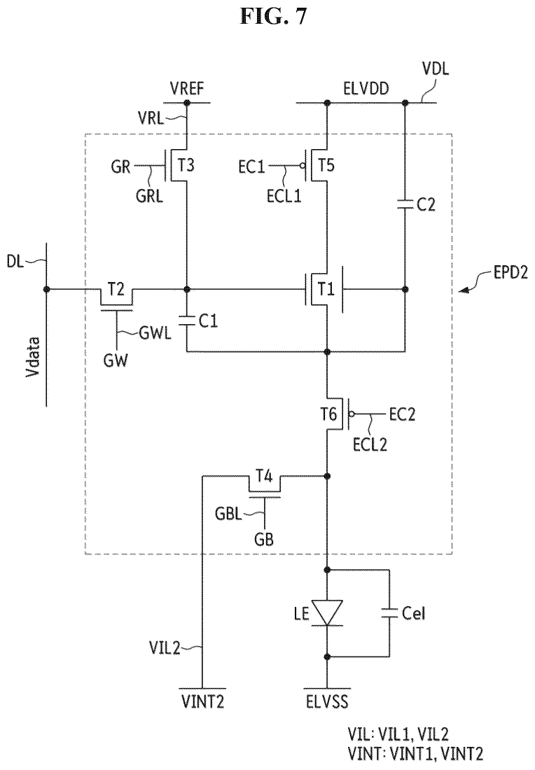

Based on control signals, power and voltages supplied from the display circuit board 300, the display driving circuit 200 may transmit a data signal Vdata (see FIGS. 6 and 7) of each of light emitting pixel drivers EPD (see FIG. 5) of the display area DA to data lines DL (see FIGS. 6 and 7).

In an embodiment, the display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and an embodiments of the present disclosure are not necessarily limited thereto. For example, the display driving circuit 200 may be mounted on the display circuit board 300.

According to an embodiment, the touch driving circuit 400 may be further mounted on the sub-region SBA of the display device 100.

Alternatively, as shown in FIG. 2, the touch driving circuit 400 may be mounted on the display circuit board 300.

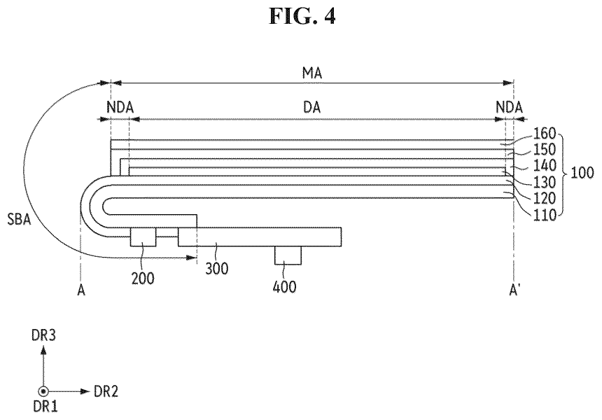

The touch driving circuit 400 may be electrically connected to a touch sensor layer 150 (see FIG. 4) of the display device 100.

As shown in FIG. 2, the bracket 13 may be located under the display device 100 (e.g., directly thereunder in a direction opposite to the third direction DR3).

The bracket 13 may include plastic or metal. In an embodiment, the bracket 13 may include a first camera hole CMH1 into which a camera device 16 is inserted, a battery hole BH into which a battery 18 is located, and a cable hole CAH through which the cable 600 connected to the display circuit board 300 passes.

The main circuit board 14 and the battery 18 may be located under the bracket 13 (e.g., in a direction opposite to the third direction DR3).

The main circuit board 14 may be a printed circuit board or a flexible printed circuit board.

In an embodiment, the main circuit board 14 may include a main processor 15, the camera device 16, and a main connector 17. The main processor 15 may be formed as an integrated circuit.

The camera device 16 may be located on both the top surface and the bottom surface of the main circuit board 14, the main processor 15 may be located on the top surface of the main circuit board 14, and the main connector 17 may be located on the bottom surface of the main circuit board 14.

The main processor 15 may control all functions of the electronic device 10.

For example, the main processor 15 may output digital video data to the display driving circuit 200 through the display circuit board 300 such that the display device 100 displays an image. In addition, the main processor 15 may receive touch data including user's touch coordinates from the touch driving circuit 400, determine whether or not the user has touched or approached the electronic device 10, and then perform an operation corresponding to the user's touch input or approach input. For example, the main processor 15 may perform an operation or execute an application indicated by an icon touched by the user.

The main processor 15 may be an application processor formed of an integrated circuit, a central processing unit, or a system chip.

The camera device 16 may process an image frame of a still image or video obtained by an image sensor in a camera mode and output it to the main processor 15.

A cable 600 having passed through the cable hole CAH of the bracket 13 may be connected to the main connector 17. Thus, the main circuit board 14 may be electrically connected to the display circuit board 300.

The battery 18 may be located so as not to overlap the main circuit board 14 in the third direction DR3. The battery 18 may overlap the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 18 (e.g., in a direction opposite to the third direction DR3). In an embodiment, the lower cover 12 may be fixed by being fastened to the bracket 13. The lower cover 12 may form the upper side surface, lower side surface, and bottom surface of the electronic device 10. The lower cover 12 may include plastic, metal, or both plastic and metal.

The lower cover 12 may include a second camera hole CMH2 through which the bottom surface of the camera device 16 is exposed. The position of the camera device 16 and the positions of the first camera hole CMH1 and the second camera hole CMH2 corresponding to the camera device 16 are not necessarily limited to those illustrated in FIG. 2.

Next, the display device 100 according to an embodiment will be described.

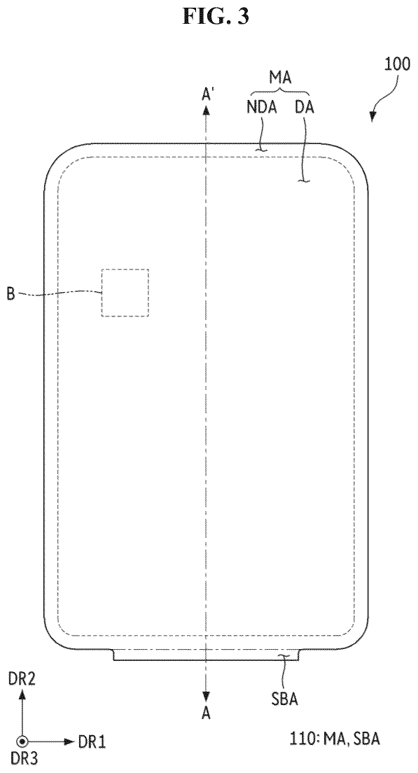

FIG. 3 is a plan view illustrating the display device of FIG. 2. FIG. 4 is a cross-sectional view taken along line A-A′ of FIG. 3.

FIGS. 3 and 4 illustrate the display device 100 with a part of the sub-region SBA in a bent state.

In an embodiment, the display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, embodiments of the present disclosure are not necessarily limited thereto, and may be applied to a display device including an organic insulating material, an organic light emitting material, and a metal material.

In an embodiment, the display device 100 may be formed to be flat, but embodiments of the present disclosure are not necessarily limited thereto. For example, the display device 100 may include a curved portion formed at left and right ends and having a constant curvature or a varying curvature. In addition, in an embodiment the display device 100 may be formed to be flexible so that it can be curved, bent, folded, or rolled.

Referring to FIG. 3, at least one surface of the display device 100 includes the main region MA from which light for displaying an image is emitted.

The display area DA may, in plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a selected curvature or may be right-angled. The planar shape of the display area DA is not necessarily limited to the rectangular shape, and may be formed in another polygonal shape, a circular shape or an elliptical shape.

In an embodiment, the display area DA may be located in a majority of the main region MA. The display area DA may be located at the center of the main region MA (e.g., in a plan view).

Referring to FIG. 4, the display device 100 may further include the sub-region SBA protruding in the second direction DR2 from at least a part of one side of the main region MA, such as a lower side in the second direction DR2.

Since a part of the sub-region SBA is transformed into a bent shape, another part of the sub-region SBA may be located on the rear surface of the display device 100.

According to an embodiment, the display device 100 includes a substrate 110, a circuit layer 120 located on the substrate 110, and an element layer 130 located on the circuit layer 120.

The display device 100 may further include an encapsulation layer 140 located on (e.g., disposed directly thereon) the element layer 130, and a touch sensor layer 150 located on (e.g., disposed directly thereon) the encapsulation layer 140.

In an embodiment, the display device 100 may further include a polarization layer 160 located on the touch sensor layer 150 (e.g., disposed directly thereon in the third direction DR3) to reduce reflection of external light.

The substrate 110 may include the main region MA corresponding to the display surface, and the sub-region SBA protruding in the second direction DR2 from at least a part of one side of the main region MA. A thickness direction of the substrate 110 may be the third direction DR3.

The main region MA of the substrate 110 may include the display area DA from which light is emitted, and the non-display area NDA located around the display area DA (e.g., in a plan view).

According to an embodiment, the element layer 130 may include light emitting elements LE (see FIGS. 6, 7, and 8) respectively located in the emission areas EA (see FIG. 5).

In an embodiment, the circuit layer 120 may include the light emitting pixel drivers EPD (see FIG. 5) electrically connected to light emitting elements LE, and an initialization voltage line VIL (see FIGS. 6 and 7) that transmit an initialization voltage VINT (see FIGS. 6 and 7) to the light emitting pixel drivers EPD.

The circuit layer 120 may further include the data lines DL (see FIGS. 6 and 7) that transmit the data signals Vdata (see FIGS. 6 and 7) of the light emitting pixel drivers EPD (see FIG. 5).

The encapsulation layer 140 may cover the element layer 130. In an embodiment, the encapsulation layer 140 may include a structure in which two or more inorganic layers and at least one organic layer are alternately stacked (e.g., in the third direction DR3).

The touch sensor layer 150 may be located on the encapsulation layer 140 and may correspond to (e.g., overlap with in the third direction DR3) the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, to prevent the deterioration of visibility of an image due to external light reflection.

As a part of the sub-region SBA is transformed into a bent shape, the display driving circuit 200 mounted in the sub-region SBA, and the display circuit board 300 connected to one side of the sub-region SBA may be located under the substrate 110 (e.g., in a direction opposite to the third direction DR3).

The display driving circuit 200 may be electrically connected to the data lines DL (see FIGS. 6, 7, and 10) of the circuit layer 120. The display driving circuit 200 may transmit the data signals Vdata (see FIGS. 6 and 7) of the light emitting pixel drivers EPD (see FIG. 5) through the data lines DL based on control signals and power voltages supplied from the display circuit board 300.

In an embodiment, the display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and an embodiments of the present disclosure are not necessarily limited thereto. For example, the display driving circuit 200 may be mounted on the display circuit board 300.

One end of the display circuit board 300 may be attached onto pads located on one edge of the sub-region SBA of the display device 100 by using an anisotropic conductive film.

In an embodiment, the display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

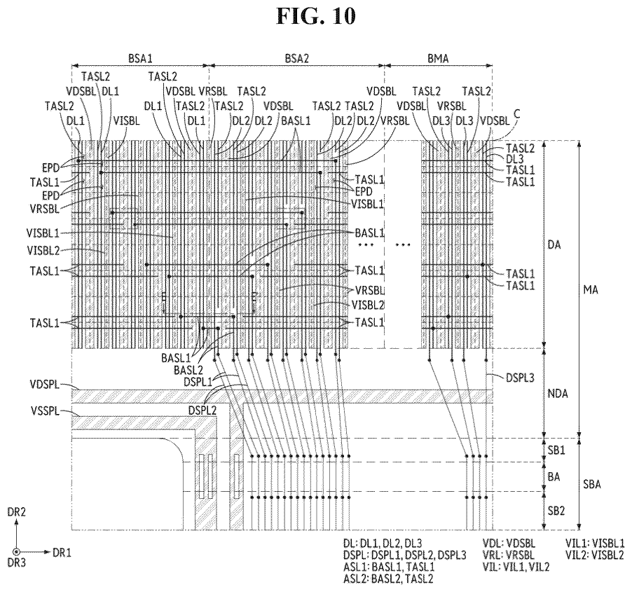

The display circuit board 300 may be connected to signal pads SPD (see FIG. 10) located on one side of the sub-region SBA.

In an embodiment, a touch driving circuit 400 may be mounted on the display circuit board 300 (e.g., in a direction opposite to the third direction DR3).

The touch driving circuit 400 may be electrically connected to the touch sensor layer 150 of the display device 100.

In an embodiment, the touch driving circuit 400 may apply a touch driving signal to driving lines of the touch sensor layer 150, and receive a touch sensing signal from sensing lines. Further, the touch driving circuit 400 may detect charge variation amounts of capacitances based on the touch sensing signal, thereby determining whether a user has touched or approached.

The user's touch means that an object such as a pen or a user's finger is in direct contact with the top surface of the cover window located on the touch sensor layer. The user's approach means that the object such as the pen or the user's finger hovers over the top surface of the cover window and is not in direct contact with the cover window.

The touch driving circuit 400 may output touch data including the user's touch coordinates to the main processor 15 (see FIG. 2).

FIG. 5 is a schematic diagram showing part B of FIG. 3.

As illustrated in FIG. 5, the display area DA may include the emission areas EA from which light is emitted, and a non-emission area NEA that is a space between the emission areas EA and from which no light is emitted.

Each of the emission areas EA may be a unit area that emits light in a wavelength band corresponding to one color of two or more different colors with a luminance corresponding to an image signal.

In an embodiment, each of the emission areas EA may be arranged in a quadrilateral shape (e.g., in a plan view).

However, this is only an example, and the planar shape of the emission areas EA according to an embodiment is not necessarily limited to that illustrated in FIG. 5. For example, the emission areas EA may have, in plan view, a circular shape, an elliptical shape, or a polygonal shape such as a rectangle, a square, a hexagon, or an octagon, rather than a rhombus.

The emission areas EA may include first emission areas EA1 that emit light in a first wavelength band, second emission areas EA2 that emit light in a second wavelength band lower than the first wavelength band, and third emission areas EA3 that emit light in a third wavelength band lower than the second wavelength band.

For example, in an embodiment the first wavelength band may be in a range from about 600 nm to about 750 nm and may correspond to a red color. The second wavelength band may be in a range from about 480 nm to about 560 nm and may correspond to a green color. The third wavelength band may be in a range from about 370 nm to about 460 nm and may correspond to a blue color.

However, this is only an example, and the first wavelength band, the second wavelength band, and the third wavelength band according to an embodiment are not necessarily limited thereto.

Since the emission areas EA include the first emission area EA1, the second emission area EA2, and the third emission area EA3, each of unit pixels PX may be provided by a combination of one or more first emission areas EA1, one or more second emission areas EA2, and one or more third emission areas EA3 adjacent to each other among the emission areas EA.

Each of the unit pixels PX may be a unit for displaying various colors including white. For example, lights of various colors displayed by the unit pixels PX may be implemented as a mixture of lights emitted from two or more emission areas EA included in each unit pixel PX.

The third emission area EA3 may have a width greater than that of the first emission area EA1, and the first emission area EA1 may have a width greater than that of the second emission area EA2. However, this is merely an example, and the width of each of the emission areas EA is not necessarily limited to that illustrated in FIG. 5.

In an embodiment, the first emission areas EA1 and the third emission areas EA3 may be alternately arranged in the second direction DR2.

In an embodiment, the second emission areas EA2 may be arranged side by side in the second direction DR2.

Further, the first emission area EA1, the second emission area EA2, the third emission area EA3, and the second emission area EA2 may be arranged repeatedly in the first direction DR1.

For example, in the first direction DR1, the first emission area EA1 may be located between adjacent second emission areas EA2, the second emission area EA2 may be located between the first emission area EA1 and the third emission area EA3, and the third emission area EA3 may be located between adjacent second emission areas EA2.

In this case, each of the unit pixels PX may include one first emission area EA1 and one third emission area EA3 adjacent to each other in the second direction DR2, and two second emission areas EA2 adjacent thereto in the first direction DR1. However, this is only an example, and the arrangement pattern of the emission areas EA and the components of the unit pixel PX according to an embodiment are not necessarily limited to the above description.

According to an embodiment, the circuit layer 120 (see FIG. 4) may include the light emitting pixel drivers EPD arranged in the first direction DR1 and the second direction DR2 in the display area DA.

The light emitting pixel drivers EPD may be respectively electrically connected to the light emitting elements LE (see FIGS. 6, 7, and 8) of the element layer 130 (see FIG. 4). The light emitting elements LE may be located in the emission areas EA, respectively.

In an embodiment, the light emitting pixel drivers EPD may include first light emitting pixel drivers EPD1 electrically connected to the light emitting elements LE of the first emission areas EA1, second light emitting pixel drivers EPD2 electrically connected to the light emitting elements LE of the second emission areas EA2, and third light emitting pixel drivers EPD3 electrically connected to the light emitting elements LE of the third emission areas EA3.

For example, the first light emitting pixel drivers EPD1 and the third light emitting pixel drivers EPD3 may be arranged alternately with each other in the second direction DR2.

The second light emitting pixel drivers EPD2 may be arranged side by side in the second direction DR2.

In the first direction DR1, the first light emitting pixel drivers EPD1, the second light emitting pixel drivers EPD2 and the third light emitting pixel drivers EPD3 may be arranged alternately one by one in sequence.

FIG. 6 is an equivalent circuit diagram showing the third light emitting pixel driver of FIG. 5. FIG. 7 is an equivalent circuit diagram showing the second light emitting pixel driver of FIG. 5.

As illustrated in FIGS. 6 and 7, the light emitting pixel drivers EPD of the circuit layer 120 (see FIG. 4) may be electrically connected to the data line DL for transmitting the data signal Vdata, a first power line VDL for transmitting a first power ELVDD, a reference voltage line VRL for transmitting a reference voltage VREF, and the initialization voltage line VIL for transmitting the initialization voltage VINT.

Further, in an embodiment the light emitting pixel drivers EPD may be electrically connected to a scan write line GWL that transmits a scan write signal GW, a reset control line GRL that transmits a reset control signal GR, a bias control line GBL that transmits a bias control signal GB, a first emission control line ECL1 that transmits a first emission control signal EC1, and a second emission control line ECL2 that transmits a second emission control signal EC2.

The light emitting elements LE of the element layer 130 (see FIG. 4) may be respectively electrically connected between the light emitting pixel drivers EPD of the circuit layer 120 (see FIG. 4) and a second power source ELVSS.

The second power source ELVSS may be at a voltage level lower than that of a first power source ELVDD.

For example, in an embodiment the anode electrode of the light emitting element LE is electrically connected to the light emitting pixel driver EPD, and the cathode electrode of the light emitting element LE may be applied with a second power ELVSS having a voltage level lower than the first power ELVDD.

In an embodiment, each of the light emitting pixel drivers EPD may include a first transistor T1 generating a driving current of each of the light emitting elements LE, two or more transistors T2 to T6 electrically connected to the first transistor T1, and one or more capacitors C1 and C2.

The second transistor T2 may be electrically connected between the gate electrode of the first transistor T1 and the data line DL.

In an embodiment, the second transistor T2 may be turned on by the scan write signal GW of the scan write line GWL.

When the second transistor T2 is turned on, the data signal Vdata of the data line DL may be transmitted to the gate electrode of the first transistor T1.

When the voltage difference between the gate electrode of the first transistor T1 and the second electrode of the first transistor T1 is greater than or equal to the threshold voltage of the first transistor T1 due to the data signal Vdata applied to the gate electrode of the first transistor T1, the first transistor T1 may be turned on. Accordingly, a drain-source current of the first transistor T1 may be generated to have a magnitude corresponding to the data signal Vdata.

The third transistor T3 may be electrically connected between the gate electrode of the first transistor T1 and the reference voltage line VRL.

In an embodiment, the third transistor T3 may be turned on by the reset control signal GR of the reset control line GRL.

When the third transistor T3 is turned on, the potential of the gate electrode of the first transistor T1 may be reset to the reference voltage VREF of the reference voltage line VRL.

The fourth transistor T4 may be electrically connected between the light emitting element LE and the initialization voltage line VIL.

In an embodiment, the fourth transistor T4 may be turned on by the bias control signal GB of the bias control line GBL.

When the fourth transistor T4 is turned on, the potential of the anode electrode of the light emitting element LE may be initialized to the initialization voltage VINT of the initialization voltage line VIL.

The fifth transistor T5 may be electrically connected between the first electrode of the first transistor T1 and the first power line VDL.

In an embodiment, the fifth transistor T5 may be turned on by the first emission control signal EC1 of the first emission control line ECL1.

When the fifth transistor T5 is turned on, the first power ELVDD of the first power line VDL may be transmitted to the first electrode of the first transistor T1.

The sixth transistor T6 may be electrically connected between the second electrode of the first transistor T1 and the light emitting element LE.

In an embodiment, the sixth transistor T6 may be turned on by the second emission control signal EC2 of the second emission control line ECL2.

When the sixth transistor T6 is turned on, the drain-source current of the first transistor T1 generated to have the magnitude corresponding to the data signal Vdata may be transmitted to the light emitting element LE through the sixth transistor T6.

Accordingly, the light emitting element LE may emit light having a luminance corresponding to the data signal Vdata.

The first capacitor C1 may be electrically connected between the gate electrode of the first transistor T1 and the second electrode of the first transistor T1.

Accordingly, the first capacitor C1 may be charged with the data signal Vdata applied to the gate electrode of the first transistor T1, and the turn-on of the first transistor T1 may be maintained for a selected period due to the voltage charged in the first capacitor C1.

A second capacitor C2 may be electrically connected between the second electrode of the first transistor T1 and the first power line VDL.

The voltage of the first capacitor C1 may correspond to the potential difference between the gate electrode of the first transistor T1 and the second electrode of the first transistor T1, may be changed by the data signal Vdata, and may be divided by the second capacitor C2. Accordingly, the threshold voltage of the first transistor T1 may be compensated.

According to an embodiment, the first transistor T1 may include a gate electrode and a gate additional electrode facing opposite surfaces of a channel portion.

The gate electrode of the first transistor T1 may be electrically connected to the second transistor T2.

In an embodiment, the gate additional electrode of the first transistor T1 may be electrically connected to the second electrode of the first transistor T1.

Accordingly, when the data signal Vdata is applied to the gate electrode of the first transistor T1 such that the first transistor T1 is in a turned-on state, compared to a portion of the channel portion of the first transistor T1, which is adjacent to the gate electrode, the other portion of the channel portion of the first transistor T1, which is adjacent to the gate additional electrode, may not be activated.

Therefore, since the electron mobility in the channel portion of the first transistor T1 decreases, the slope of a current curve representing a relationship between the drain-source current and the voltage of the gate electrode of the first transistor T1 may become gentle. Accordingly, a driving voltage range of the first transistor T1 may be widened, which may facilitate luminance control.

According to an embodiment, as illustrated in FIGS. 6 and 7, the initialization voltage line VIL may include a first initialization voltage line VIL1 that transmits a first initialization voltage VINT1, and a second initialization voltage line VIL2 that transmits a second initialization voltage VINT2 having a different voltage level from the first initialization voltage VINT1.

As illustrated in FIG. 6, the third light emitting pixel drivers EPD3 may be electrically connected to the first initialization voltage line VIL1 that transmits the first initialization voltage VINT1.

As illustrated in FIG. 7, the second light emitting pixel drivers EPD2 may be electrically connected to the second initialization voltage line VIL2 that transmits the second initialization voltage VINT2.

As a result, the light emitting element LE of the third emission area EA3 may be initialized to the first initialization voltage VINT1, and the light emitting element LE of the second emission area EA2 may be initialized to the second initialization voltage VINT2.

In this way, even if the light emitting element LE of the third emission area EA3 and the light emitting element LE of the second emission area EA2 have different parasitic capacitances Cel due to different organic light emitting materials and different widths, they may be appropriately initialized by the first initialization voltage VINT1 and the second initialization voltage VINT2 of different voltage levels, respectively.

Therefore, since defects such as partial stains and image quality degradation may be reduced, the display quality of the display device 100 may be increased.

According to an embodiment, the first light emitting pixel drivers EPD1 may be electrically connected to one of the first initialization voltage line VIL1 (see FIG. 6) and the second initialization voltage line VIL2 (see FIG. 7).

As an example, when the light emitting element LE of the first emission area EA1 has the parasitic capacitance Cel in a similar range to the light emitting element LE of the third emission area EA3, the first light emitting pixel drivers EPD1 may be electrically connected to the first initialization voltage line VIL1 (see FIG. 6) together with the third light emitting pixel drivers EPD3.

As another example, when the light emitting element LE of the first emission area EA1 has the parasitic capacitance Cel in a similar range to the light emitting element LE of the second emission area EA2, the first light emitting pixel drivers EPD1 may be electrically connected to the second initialization voltage line VIL2 (see FIG. 7) together with the second light emitting pixel drivers EPD2.

As illustrated in FIGS. 6 and 7, in an embodiment the first transistor T1 may be an N-type MOSFET.

In an embodiment, each of the second to sixth transistors T2 to T6 may be a P-type MOSFET.

Alternatively, each of the second to sixth transistors T2 to T6 may be an N-type MOSFET.

According to an embodiment, at least some of the second to sixth transistors T2 to T6 may be P-type MOSFETs. For example, the fifth transistor T5 and the sixth transistor T6 may be P-type MOSFETs, and the second transistor T2, third transistor T3, and fourth transistor T4 may be N-type MOSFETs.

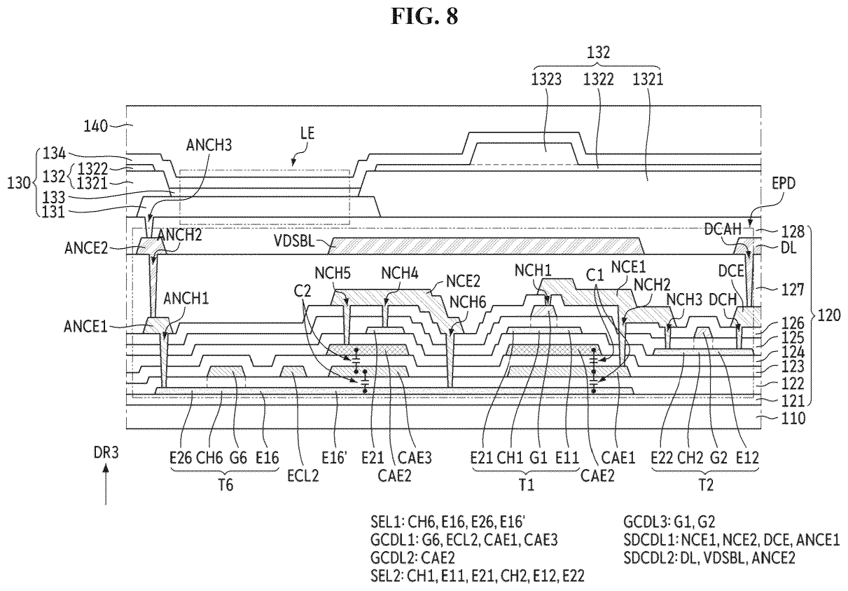

According to an embodiment, the circuit layer 120 may include a first semiconductor layer SEL1 (see FIG. 8) for providing a P-type MOSFET and a second semiconductor layer SEL2 (see FIG. 8) for providing an N-type MOSFET.

FIG. 8 is a cross-sectional view showing the first transistor, the second transistor, the sixth transistor, the first and second capacitors, and the light emitting element of FIGS. 6 and 7.

Referring to FIG. 8, the display device 100 according to an embodiment may include the substrate 110, the circuit layer 120 on the substrate 110, and the element layer 130 on the circuit layer 120.

The display device 100 may further include the encapsulation layer 140 on (e.g., disposed directly thereon) the element layer 130.

According to an embodiment, the circuit layer 120 may include the first semiconductor layer SEL1 located on the substrate 110 (e.g., in the third direction DR3), a first gate insulating layer 122 covering the first semiconductor layer SEL1, a first gate conductive layer GCDL1 located on the first gate insulating layer 122 (e.g., disposed directly thereon in the third direction DR3), a second gate insulating layer 123 covering the first gate conductive layer GCDL1, a second gate conductive layer GCDL2 located on the second gate insulating layer 123 (e.g., disposed directly thereon in the third direction DR3), a first interlayer insulating layer 124 covering the second gate conductive layer GCDL2, the second semiconductor layer SEL2 located on the first interlayer insulating layer 124 (e.g., disposed directly thereon in the third direction DR3), a third gate insulating layer 125 covering the second semiconductor layer SEL2, a third gate conductive layer GCDL3 located on the third gate insulating layer 125 (e.g., disposed directly thereon in the third direction DR3), a second interlayer insulating layer 126 covering the third gate conductive layer GCDL3, and a first source-drain conductive layer SDCDL1 located on the second interlayer insulating layer 126 (e.g., disposed directly thereon in the third direction DR3).

According to an embodiment, the circuit layer 120 may further include a first planarization layer 127 covering the first source-drain conductive layer SDCDL1, a second source-drain conductive layer SDCDL2 located on the first planarization layer 127 (e.g., disposed directly thereon in the third direction DR3), and a second planarization layer 128 covering the second source-drain conductive layer SDCDL2.

According to an embodiment, the circuit layer 120 may further include the buffer layer 121 covering the substrate 110. In this embodiment, the first semiconductor layer SEL1 may be located on the buffer layer 121.

As illustrated in FIGS. 6 and 7, in an embodiment each of the light emitting pixel drivers EPD may include the first transistor T1, and the second transistor T2, the third transistor T3, the fourth transistor T4, the fifth transistor T5, the sixth transistor T6, the first capacitor C1, and the second capacitor C2 that are electrically connected to the first transistor T1.

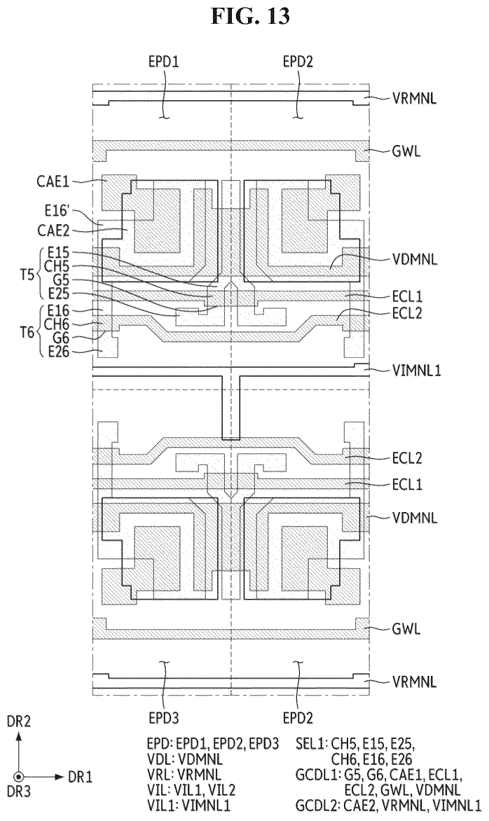

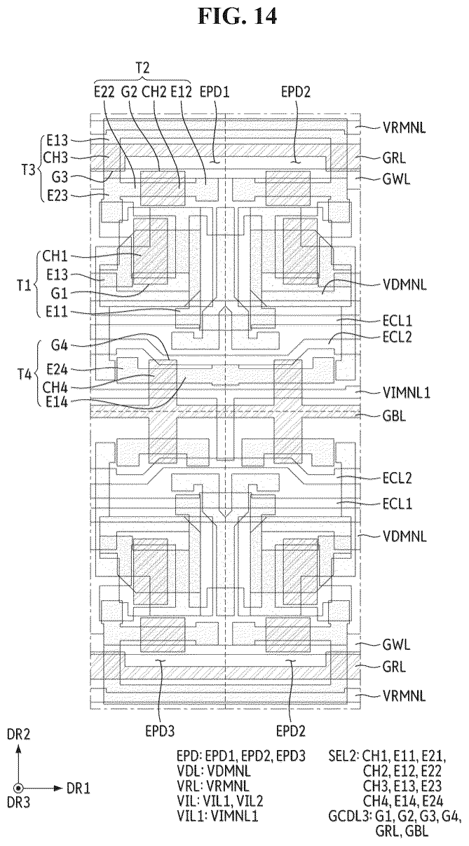

In an embodiment, the first transistor T1, the second transistor T2, the third transistor T3, the fourth transistor T4, the fifth transistor T5, and the sixth transistor T6 may include gate electrodes G1, G2, G3, and G4 (see FIG. 14), and G5 and G6 (see FIG. 13), channel portions CH1, CH2, CH3, and CH4 (see FIG. 14), and CH5 and CH6 (see FIG. 13) overlapping the gate electrodes, first electrode portions E11, E12, E13, and E14 (See FIG. 14), and E15 and E16 (see FIG. 13) connected to one sides of the channel portions, and second electrode portions E21, E22, E23, and E24 (see FIG. 14), and E25 and E26 (see FIG. 13) connected to the other sides of the channel portions, respectively.

In the following, the “first electrode portion” and the “second electrode portion” electrically connected to the two opposite ends of the “channel portion” of the “transistor” may also be referred to as the “first electrode” and the “second electrode,” respectively.

In an embodiment, the first, second, third and fourth transistors T1, T2, T3, and T4 may be N-type MOSFETs, and the fifth and sixth transistors T5 and T6 may be P-type MOSFETs.

The channel portion CH5, the first electrode portion E15, and the second electrode portion E25 of the fifth transistor T5 (see FIG. 13), and the channel portion CH6, the first electrode portion E16, and the second electrode portion E26 of the sixth transistor T6 (see FIG. 13), each provided as a P-type MOSFET, may be arranged in the first semiconductor layer SEL1.

The gate electrodes G5 and G6 (see FIG. 13) of the fifth transistor T5 and T6, respectively, may be arranged in the first gate conductive layer GCDL1.

As an example, in an embodiment the first semiconductor layer SEL1 may include a silicon semiconductor material such as polysilicon or amorphous silicon.

For example, in an embodiment the sixth transistor T6 may include the channel portion CH6 located in the first semiconductor layer SEL1, the first electrode portion E16 and E16′ located in the first semiconductor layer SEL1 and connected to the one side of the channel portion CH6, the second electrode E26 located in the first semiconductor layer SEL1 and connected to the other side of the channel portion CH6, and the gate electrode G6 located in the first gate conductive layer GCDL1 and overlapping the channel portion CH6.

Since the fifth transistor T5 is the same P-type MOSFET as the sixth transistor T6, redundant descriptions will be omitted below for economy of explanation.

The channel portions CH1, CH2, CH3, and CH4 (see FIG. 14), the first electrode portions E11, E12, E13, and E14 (see FIG. 14), and the second electrode portions E21, E22, E23, E24 (see FIG. 14) of the first, second, third, and fourth transistors T1, T2, T3, and T4, respectively, each provided as an N-type MOSFET, may be arranged in the first semiconductor layer SEL1.

The gate electrodes G1, G2, G3, and G4 (see FIG. 14) of the first, second, third, and fourth transistors T1, T2, T3, and T4, respectively, may be arranged in the third gate conductive layer GCDL3.

As an example, in an embodiment the second semiconductor layer SEL2 may include an oxide semiconductor material.

For example, in an embodiment the first transistor T1 may include the channel portion CH1 located in the second semiconductor layer SEL2, the first electrode E11 located in the second semiconductor layer SEL2 and connected to the one side of the channel portion CH1, the second electrode E21 located in the second semiconductor layer SEL2 and connected to the other side of the channel portion CH1, and the gate electrode G1 located in the third gate conductive layer GCDL3 and overlapping the channel portion CH1.

The top surface of the channel portion CH1 of the first transistor T1 may face the gate electrode G1.

In addition, the bottom surface of the channel portion CH1 of the first transistor T1 may face a second capacitor electrode CAE2 electrically connected to the second electrode E21 of the first transistor T1.

For example, in an embodiment the second capacitor electrode CAE2 may be a gate additional electrode of the first transistor T1.

In an embodiment, the second transistor T2 may include the channel portion CH2 located in the second semiconductor layer SEL2, the first electrode E12 located in the second semiconductor layer SEL2 and connected to the one side of the channel portion CH2, the second electrode E22 located in the second semiconductor layer SEL2 and connected to the other side of the channel portion CH2, and the gate electrode G2 located in the third gate conductive layer GCDL3 and overlapping the channel portion CH2.

The first electrode E12 of the second transistor T2 may be electrically connected to the data line DL through a data connection electrode DCE.

In an embodiment, the data connection electrode DCE may be located in the first source-drain conductive layer SDCDL1 and may be electrically connected to the first electrode E12 of the second transistor T2 through a data connection hole DCH.

The data connection hole DCH may penetrate the second interlayer insulating layer 126 and the third gate insulating layer 125.

The data line DL may be located in the second source-drain conductive layer SDCDL2, and may be electrically connected to the data connection electrode DCE through a data additional connection hole DCAH penetrating the first planarization layer 127.

In an embodiment, the second electrode E22 of the second transistor T2 may be electrically connected to the gate electrode G1 of the first transistor T1 through a first node connection electrode NCE1.

The first node connection electrode NCE1 may be located in the first source-drain conductive layer SDCDL1.

In an embodiment, the first node connection electrode NCE1 may be electrically connected to the gate electrode G1 of the first transistor T1 through a first node connection hole NCH1, electrically connected to a first capacitor electrode CAE1 through a second node connection hole NCH2, and electrically connected to the second electrode E22 of the second transistor T2 through a third node connection hole NCH3.

The first capacitor electrode CAE1 may be located in the first gate conductive layer GCDL1.

In an embodiment, the second electrode E21 of the first transistor T1 may be electrically connected to the first electrode E16 of the sixth transistor T6 through a second node connection electrode NCE2.

The second node connection electrode NCE2 may be located in the first source-drain conductive layer SDCDL1.

In an embodiment, the second node connection electrode NCE2 may be electrically connected to the second electrode E21 of the first transistor T1 through a fourth node connection hole NCH4, electrically connected to the second capacitor electrode CAE2 through a fifth node connection hole NCH5, and electrically connected to the first electrode E16 of the sixth transistor T6 through a sixth node connection hole NCH6.

The second capacitor electrode CAE2 may be located in the second gate conductive layer GCDL2.

The first capacitor electrode CAE1 is electrically connected to the gate electrode G1 of the first transistor T1, and the second capacitor electrode CAE2 is electrically connected to the second electrode E21 of the first transistor T1. Accordingly, the first capacitor C1 may be provided by the region where the first capacitor electrode CAE1 and the second capacitor electrode CAE2 overlap each other.

A third capacitor electrode CAE3 may be located in the first gate conductive layer GCDL1 while being spaced apart from the first capacitor electrode CAE1.

The third capacitor electrode CAE3 may be connected to a power main line VDMNL (see FIG. 13). For example, the third capacitor electrode CAE3 may be a part of the power main line VDMNL (see FIG. 13).

The second capacitor electrode CAE2 may overlap the first capacitor electrode CAE1 and the third capacitor electrode CAE3 (e.g., in the third direction DR3).

In addition, an electrode extension E16′ connected to the first electrode E16 of the sixth transistor T6 may overlap with the first capacitor electrode CAE1 and the third capacitor electrode CAE3.

Therefore, the first capacitor C1 may also be provided by the region where the electrode extension E16′ and the first capacitor electrode CAE1 overlap each other.

In addition, the second capacitor C2 may be provided by the regions where the second capacitor electrode CAE2 and the electrode extension E16′ respectively overlap the third capacitor electrode CAE3.

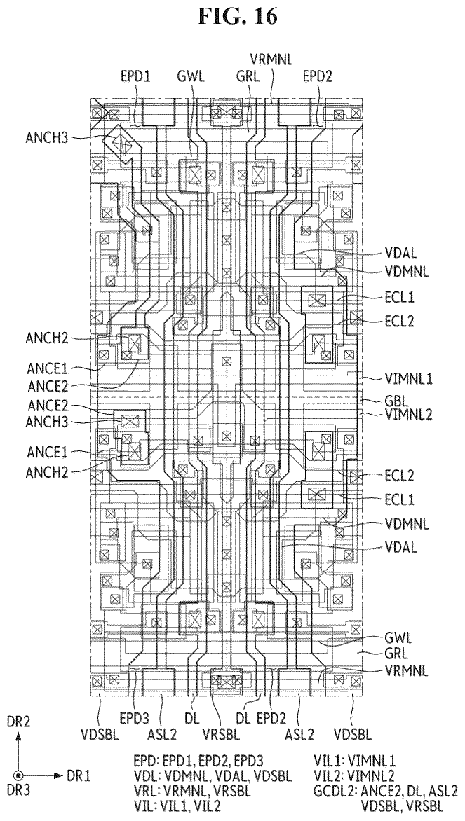

In an embodiment, the first power line VDL (see FIGS. 6 and 7) may include the power main line VDMNL (see FIG. 13) located in the first gate conductive layer GCDL1 and extending in the first direction DR1, and a power sub-line VDSBL (see FIG. 16) located in the second source-drain conductive layer SDCDL2 and extending in the second direction DR2.

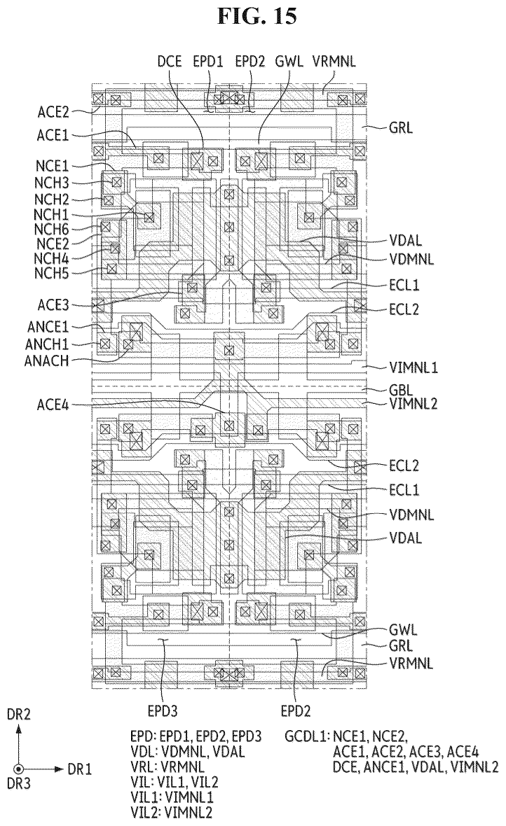

The first power line VDL (see FIGS. 6 and 7) may further include a power additional line VDAL (see FIG. 15) located in the first source-drain conductive layer SDCDL1 and extending in the first direction DR1.

In this way, the first power ELVDD (see FIGS. 6 and 7) may be transmitted to the display area DA with relatively low resistance overall.

The second electrode E26 of the sixth transistor T6 may be electrically connected to an anode electrode 131 of the light emitting element LE through a first anode connection electrode ANCE1 and a second anode connection electrode ANCE2.

The first anode connection electrode ANCE1 may be located in the first source-drain conductive layer SDCDL1 on the second interlayer insulating layer 126, and may be electrically connected to the second electrode E26 of the six transistor T6 through a first anode connection hole ANCH1.

In an embodiment, the first anode connection hole ANCH1 may penetrate the second interlayer insulating layer 126, the third gate insulating layer 125, the first interlayer insulating layer 124, the second gate insulating layer 123, and the first gate insulating layer 122.

The second anode connection electrode ANCE2 may be located on the second source-drain conductive layer SDCDL2 on the first planarization layer 127 (e.g., disposed directly thereon in the third direction DR3), and electrically connected to the first anode connection electrode ANCE1 through a second anode connection hole ANCH2 penetrating the first planarization layer 127.

In an embodiment, the anode electrode 131 may be located on the second planarization layer 128 (e.g., disposed directly thereon in the third direction DR3), and may be electrically connected to the second anode connection electrode ANCE2 through a third anode connection hole ANCH3 penetrating the second planarization layer 128.

The element layer 130 may be located on the circuit layer 120, and may include the light emitting elements LE respectively corresponding to the emission areas EA.

Each of the light emitting elements LE may include the anode electrode 131 and a cathode electrode 134 facing each other, and a light emitting layer 133 located between the anode electrode 131 and the cathode electrode 134 (e.g., in the third direction DR3).

For example, the element layer 130 may include the anode electrodes 131 located in the emission areas EA, a pixel defining layer 132 located in the non-emission area and covering the edge of the anode electrode 131 and exposing a central portion of the anode electrode 131, the light emitting layers 133 located on the portions of the anode electrodes 131 exposed by the pixel defining layer 132, and the cathode electrode 134 located on the light emitting layers 133 and the pixel defining layer 132.

In an embodiment, the pixel defining layer 132 may include a first pixel defining layer 1321 located on (e.g., disposed directly thereon) the second planarization layer 128, a second pixel defining layer 1322 located on the first pixel defining layer 1321 (e.g., disposed directly thereon in the third direction DR3), and a spacer layer 1323 located on a portion of the second pixel defining layer 1322 (e.g., disposed directly thereon in the third direction DR3).

As an example, the first pixel defining layer 1321 may include a light-absorbing insulating material that absorbs light or a light-blocking insulating material that blocks light.

Alternatively, in an embodiment each of the light emitting elements LE may further include a first common layer located between the anode electrode 131 and the light emitting layer 133, and a second common layer located between the light emitting layer 133 and the cathode electrode 134.

The anode electrode 131 may be located in each of the emission areas EA and may be electrically connected to one light emitting pixel driver EPD of the circuit layer 120. This anode electrode 131 may be referred to as a pixel electrode.

The light emitting layer 133 may include an organic light emitting material that converts electron-hole pairs into light.

The cathode electrode 134 may be located in the display area DA including the emission areas EA. The voltage of the second power source ELVSS (see FIG. 5) may be commonly applied to the cathode electrode 134. The cathode electrode 134 may be referred to as a common electrode.

The encapsulation layer 140 may be located on the circuit layer 120 and cover the element layer 130.

As an example, in an embodiment the encapsulation layer 140 may include a first encapsulation layer located on the element layer 130 (e.g., disposed directly thereon in the third direction DR3) and containing an inorganic insulating material, a second encapsulation layer located on the first encapsulation layer (e.g., disposed directly thereon in the third direction DR3), overlapping the element layer 130, and containing an organic insulating material, and a third encapsulation layer located on the first encapsulation layer, covering the second encapsulation layer, and containing an inorganic insulating material.

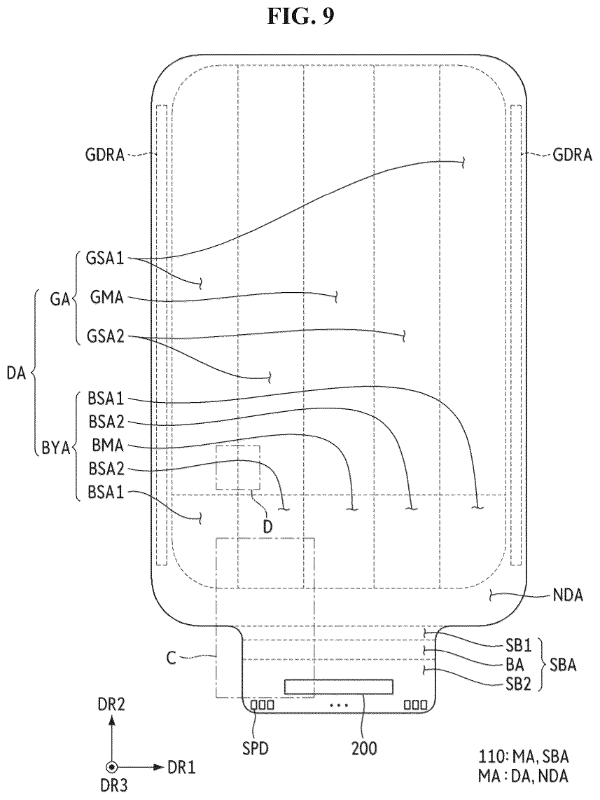

FIG. 9 is a schematic view showing the substrate of FIG. 4.

As shown in FIG. 9, the substrate 110 of the display device 100 according to an embodiment may include the main region MA corresponding to the display surface, and the sub-region SBA protruding from one side of the main region MA (e.g., a lower side in the second direction DR2).

In an embodiment, the main region MA may include the display area DA located at a majority of the center, and the non-display area NDA located at the periphery to surround the display area DA (e.g., in a plan view).

In an embodiment, the display area DA may include a bypass area BYA located on one side adjacent to the sub-region SBA, and a general area GA located in the remaining area excluding the bypass area BYA.

The bypass area BYA may include a bypass middle area BMA located at the center in the first direction DR1, a first bypass side area BSA1 parallel to the bypass middle area BMA in the first direction DR1 and in direct contact with the non-display area NDA, and a second bypass side area BSA2 located between the bypass middle area BMA and the first bypass side area BSA1 (e.g., in the first direction DR1).

The first bypass side area BSA1 may be located adjacent to the bent corner of the substrate 110 as compared to the bypass middle area BMA and the second bypass side area BSA2.

The first bypass side area BSA1 and the second bypass side area BSA2 may be located between the bypass middle area BMA and the non-display area NDA on both sides of the bypass middle area MDDA in the first direction DR1.

The general area GA may include a general middle area GMA connected to (e.g., directly connected thereto) the bypass middle area BMA of the bypass area BYA in the second direction DR2, a first general side area GSA1 connected to (e.g., directly connected thereto) the first bypass side area BSA1 of the bypass area BYA in the second direction DR2, and a second general side area GSA2 connected to (e.g., directly connected thereto) the second bypass side area BSA2 of the bypass area BYA in the second direction DR2.

The non-display area NDA may include a gate driving circuit area GDRA where a gate driving circuit is located.

The gate driving circuit area GDRA may be disposed in the non-display area NDA and face one side of the display area DA extending in the second direction DR2.

The gate driving circuit of the gate driving circuit area GDRA may sequentially transmit gate signals to gate lines.

In an embodiment, the gate lines may include the scan write line GWL (see FIGS. 6 and 7) for transmitting the scan write signal GW (FIGS. 6 and 7), the reset control line GRL (see FIGS. 6 and 7) for transmitting the reset control signal GR (FIGS. 6 and 7), the bias control line GB (see FIGS. 6 and 7) for transmitting the bias control signal GB (see FIGS. 6 and 7), the first emission control line ECL1 (see FIGS. 6 and 7) for transmitting the first emission control signal EC1 (see FIGS. 6 and 7), and the second emission control line EC2 (see FIGS. 6 and 7) for transmitting the second emission control signal EC2 (see FIGS. 6 and 7).

The sub-region SBA may include the bending area BA that is transformed into a bent shape, the first sub-region SB1 located between one side (e.g., a first side in the second direction DR2) of the bending area BA and the main region MA, and the second sub-region SB2 connected to the other side (e.g., an opposite second side in the second direction DR2) of the bending area BA.

When the bending area BA is transformed into a bent shape, the second sub-region SB2 is located below the substrate 110 and overlaps the main region MA (e.g., in a direction opposite to the third direction DR3).

The display driving circuit 200 may be located in the second sub-region SB2.

In an embodiment, the signal pads SPD may be arranged at one edge of the second sub-region SB2, and may be bonded to the display circuit board 300 (see FIG. 4).

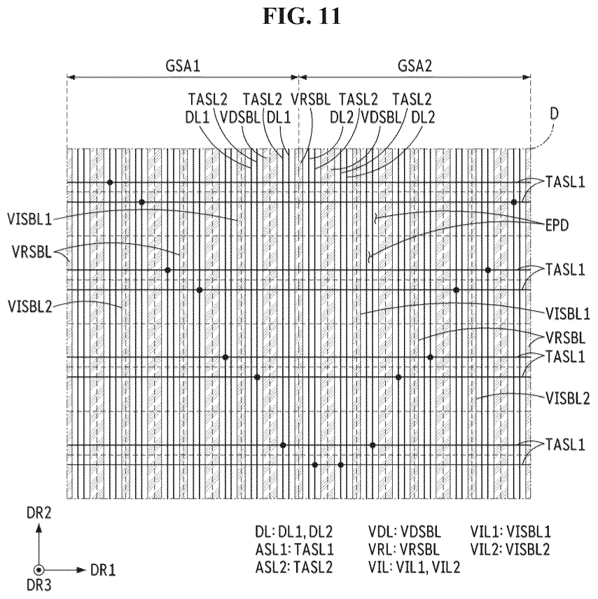

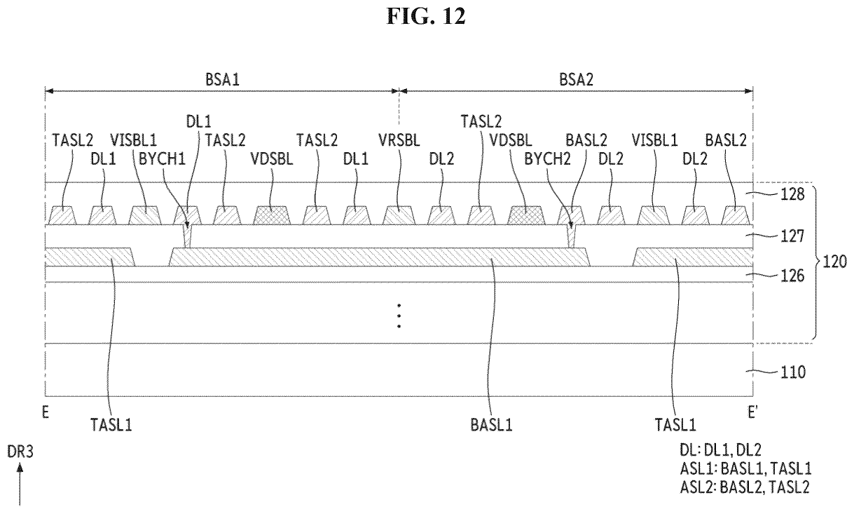

FIG. 10 is a schematic diagram showing part C of FIG. 9. FIG. 11 is a schematic diagram showing part D of FIG. 9. FIG. 12 is a cross-sectional view taken along line E-E′ of FIG. 10.

Referring to FIGS. 10 and 11, the circuit layer 120 (see FIG. 4) of the display device 100 according to an embodiment may include the light emitting pixel drivers EPD arranged side by side in the first direction DR1 and the second direction DR2, and the data lines DL that extend in the second direction DR2 and transmit the data signal Vdata to the light emitting pixel drivers EPD.

The light emitting pixel drivers EPD may be respectively electrically connected to the light emitting elements LE (see FIGS. 6 and 7) of the element layer 130 (see FIG. 4).

In an embodiment, the data lines DL may include the first data lines DL1 located in the first bypass side area BSA1 and the second data lines DL2 located in the second bypass side area BSA2. For example, the first data lines DL1 may be located closer to the non-display area NDA in the first direction DR1 than the second data lines DL.

According to an embodiment, the circuit layer 120 may further include the first auxiliary lines ASL1 located in the display area DA and extending in the first direction DR1, and the second auxiliary lines ASL2 located in the display area DA, extending in the second direction DR2, and adjacent to the data lines DL.

According to an embodiment, the circuit layer 120 may further include data supply lines DSPL located in the non-display area NDA and electrically connected to the display driving circuit 200 and the data lines DL.

The data supply lines DSPL may extend to the bypass middle area BMA and the second bypass side area BSA2.

In an embodiment, the data supply lines DSPL may include first data supply lines DSPL1 that transmit the data signal of the first data lines DL1, and second data supply lines DSPL2 that transmit the data signal of the second data lines DL2.

The first auxiliary lines ASL1 may include first bypass auxiliary lines BASL1 that are electrically connected to the first data lines DL1 adjacent to the non-display area NDA in the first direction DR1 among the data lines DL.

The second auxiliary lines ASL2 may include second bypass auxiliary lines BASL2 that are electrically connected to the first bypass auxiliary lines BASL1 and adjacent to the second data lines DL2.

In an embodiment, the first data supply lines DSPL1 may extend to the second bypass auxiliary lines BASL2 of the second bypass side area BSA2, and may be electrically connected to the first data lines DL1 through the second bypass auxiliary lines BASL2 and the first bypass auxiliary lines BASL1.

On the other hand, the second data supply lines DSPL2 may extend to the second bypass side area BSA2, and may be electrically connected directly to the second data lines DL2.

The data lines DL may further include a third data line DL3 located in the bypass middle area BMA. In addition, the data supply lines DSPL may further include a third data supply line DSPL3 that transmits the data signal of the third data line DL3.

In an embodiment, the third data supply line DSPL3 may extend to the bypass middle area BMA, and may be electrically connected directly to the third data line DL3.

The first auxiliary lines ASL1 may further include first transmission auxiliary lines TASL1 to reduce visibility of the first bypass auxiliary lines BASL1.

The first bypass auxiliary lines BASL1 may be located in the first bypass side area BSA1 and the second bypass side area BSA2 of the bypass area BYA.

The first transmission auxiliary lines TASL1 may be located between first sides of the first bypass auxiliary lines BASL1 and the non-display area NDA, between the opposite second sides of the first bypass auxiliary lines BASL1 and the bypass middle area BMA, and in the bypass middle area BMA, and the general area GA.

The second auxiliary lines ASL2 may further include second transmission auxiliary lines TASL2 to reduce visibility of the second bypass auxiliary lines BASL2.

The second bypass auxiliary lines BASL2 may be located in the second bypass side area BSA2 of the bypass area BYA.

The second transmission auxiliary lines TASL2 may be located between first sides of the second bypass auxiliary lines BASL2 and the second general side area GSA2, and in the first bypass side area BSA1, the bypass middle area BMA, and the general area GA.

At least some of the first transmission auxiliary lines TASL1 and at least some of the second transmission auxiliary lines TASL2 may transmit the second power ELVSS (see FIGS. 6 and 7).

In this way, since the first data supply lines DSPL1 do not extend directly to the first data lines DL1 of the first bypass side area BSA1 but to the second bypass auxiliary lines BASL2 of the second bypass side area BSA2, the extension length of the first data supply lines DSPL1 may be shortened. Accordingly, the width of the area required for arranging the data supply lines DSPL may be reduced.

Further, the data supply lines DSPL are not located in some of the non-display area NDA that are adjacent to the bent corners of the substrate 110.

Therefore, the width of the non-display area NDA may be further reduced by the first auxiliary line ASL1 and the second auxiliary line ASL2.

According to an embodiment, the circuit layer 120 may further include a first power supply line VDSPL and a second power supply line VSSPL that transmit the first power ELVDD (see FIGS. 6 and 7) and the second power ELVSS (see FIGS. 6 and 7), respectively.

The first power supply line VDSPL and the second power supply line VSSPL may be located in the non-display area NDA and may extend to the sub-region SBA.

According to an embodiment, each of the first power supply line VDSPL and the second power supply line VSSPL may be located in at least one of the first source-drain conductive layer SDCDL1 (see FIG. 8) or the second source-drain conductive layer SDCDL2 (see FIG. 8).

At least some of the first transmission auxiliary lines TASL1 may be electrically connected to the second power supply line VSSPL.

At least some of the second transmission auxiliary lines TASL2 may be electrically connected to at least some of the first transmission auxiliary lines TASL1 and the second power supply line VSSPL.

Referring to FIG. 15, the data lines DL and the second auxiliary lines ASL2 may be located on an insulating layer (e.g., the first planarization layer 127) covering the first auxiliary lines ASL1.

For example, in an embodiment the first auxiliary lines ASL1 may be located in the first source-drain conductive layer SDCDL1 (see FIG. 8) on the second interlayer insulating layer 126.

In an embodiment, the data lines DL and the second auxiliary lines ASL2 may be located in the second source-drain conductive layer SDCDL2 (see FIG. 8) on the first planarization layer 127.

The first bypass auxiliary line BASL1 may be electrically connected to the first data line DL1 through a first bypass connection hole BYCH1, and may be electrically connected to the second bypass auxiliary line BASL2 through a second bypass connection hole BYCH2.

Each of the first bypass connection hole BYCH1 and the second bypass connection hole BYCH2 may penetrate the first planarization layer 127.

As illustrated in FIGS. 10 and 11, the circuit layer 120 (see FIG. 4) may include the first power line VDL that transmits the first power ELVDD (see FIGS. 6 and 7), the initialization voltage line VIL that transmits the initialization voltage VINT (see FIGS. 6 and 7), and the reference voltage line VRL that transmits the reference voltage VREF (see FIGS. 6 and 7).

The first power line VDL may include the power sub-line VDSBL extending in the second direction DR2.

The reference voltage line VRL may include a reference voltage sub-line VRSBL extending in the second direction DR2.

In an embodiment, the initialization voltage line VIL may include the first initialization voltage line VIL1 that transmits the first initialization voltage VINT1 (see FIG. 6), and the second initialization voltage line VIL2 that transmits the second initialization voltage VINT2 (see FIG. 7).

The first initialization voltage line VIL1 may include a first initialization voltage sub-line VISBL1 extending in the second direction DR2.

The second initialization voltage line VIL2 may include a second initialization voltage sub-line VISBL2 extending in the second direction DR2.

According to an embodiment, as illustrated in FIG. 16, the power sub-line VDSBL and the reference voltage sub-line VRSBL may be arranged in the second source-drain conductive layer SDCDL2.

According to an embodiment, similarly to the power sub-line VDSBL and the reference voltage sub-line VRSBL of FIG. 16, the first initialization voltage sub-line VISBL1 and the second initialization voltage sub-line VISBL2 may be located in the second source-drain conductive layer SDCDL2.

As shown in FIGS. 10 and 11, each of the power sub-line VDSBL, the reference voltage sub-line VRSBL, the first initialization voltage sub-line VISBL1, and the second initialization voltage sub-line VISBL2 may be arranged adjacent to a boundary between two light emitting pixel drivers EPD that are adjacent in the first direction DR1.

In an embodiment, the power sub-line VDSBL may be arranged alternately with the reference voltage sub-line VRSBL, the first initialization voltage sub-line VISBL1, and the second initialization voltage sub-line VISBL2 (e.g., along the first direction DR1).

The reference voltage sub-line VRSBL may be arranged alternately with the first initialization voltage sub-line VISBL1 and the second initialization voltage sub-line VISBL2 (e.g., along the first direction DR1).

The first initialization voltage sub-line VISBL1 and the second initialization voltage sub-line VISBL2 may be arranged alternately with each other (e.g., along the first direction DR1).

The data line DL and the second auxiliary line ASL2 may intersect each of the light emitting pixel drivers EPD.

For example, the second auxiliary line ASL2 may be located between the power sub-line VDSBL and the data line DL in the first direction DR1.

The data line DL may be located between the second auxiliary line ASL2 and one of the reference voltage sub-line VRSBL, the first initialization voltage sub-line VISBL1, and the second initialization voltage sub-line VISBL2 in the first direction DR1.

According to an embodiment, to properly initialize the light emitting elements LE (see FIGS. 6 and 7) having the different parasitic capacitances Cel (see FIGS. 6 and 7), the initialization voltage line VIL (see FIG. 6) of the circuit layer 120 (see FIG. 4) may include the first initialization voltage line VIL1 that transmits the first initialization voltage VINT1 (see FIG. 6) and is electrically connected to third light emitting pixel drivers EPD3 (see FIG. 5), and the second initialization voltage line VIL2 that transmits the second initialization voltage VINT2 (see FIG. 7) having the different voltage level from the first initialization voltage VINT1 (see FIG. 6) and is electrically connected to the second light emitting pixel drivers EPD2 (see FIG. 5). For example, in an embodiment, the first initialization voltage line VIL1 may transmit the first initialization voltage VINT1 to a first portion of light emitting pixel drivers EPD and the second initialization voltage line VIL2 may transmit the second initialization voltage VINT2 having a different voltage from the first initialization voltage VINT1 to a second portion of the light emitting pixel drivers EPD not including the first portion.

To facilitate higher resolution of the display device 100, it is necessary to reduce the width occupied by the first initialization voltage lines VIL1 and the second initialization voltage lines VIL2 in the display area DA.

FIGS. 13, 14, 15, and 16 are plan views showing four light emitting pixel drivers adjacent to each other in a 2×2 matrix form among the light emitting pixel drivers of FIG. 5 according to an embodiment.

FIG. 13 is a plan view showing the first semiconductor layer, the first gate conductive layer, and the second gate conductive layer in the four light emitting pixel drivers. FIG. 14 is a plan view showing the second semiconductor layer and the third gate conductive layer in the four light emitting pixel drivers. FIG. 15 is a plan view showing the first source-drain conductive layer in the four light emitting pixel drivers. FIG. 16 is a plan view showing the second source-drain conductive layer in the four light emitting pixel drivers.

As illustrated in FIG. 13, according to an embodiment, the circuit layer 120 (see FIG. 4) may include the light emitting pixel drivers EPD arranged in a first direction DR1 and a second direction DR2.

In an embodiment, the light emitting pixel drivers EPD may include first light emitting pixel drivers EPD1 electrically connected to the light emitting elements LE of the first emission areas EA1, second light emitting pixel drivers EPD2 electrically connected to the light emitting elements LE of the second emission areas EA2, and third light emitting pixel drivers EPD3 electrically connected to the light emitting elements LE of the third emission areas EA3.

In an embodiment, the first light emitting pixel drivers EPD1 and the third light emitting pixel drivers EPD3 may be arranged alternately with each other in the second direction DR2.

The second light emitting pixel drivers EPD2 may be arranged side by side each other in the second direction DR2. For example, second light emitting pixel drivers EPD2 may be disposed directly adjacent to each other in the second direction DR2.

The second light emitting pixel drivers EPD2 may be adjacent to (e.g., immediately adjacent thereto) the first light emitting pixel drivers EPD1 and the third light emitting pixel drivers EPD3 in the first direction DR1.

In an embodiment, each of the light emitting pixel drivers EPD may include the fifth transistor T5 and the sixth transistor T6, each of which is provided as a P-type MOSFET.

As shown in FIG. 13, according to an embodiment, the circuit layer 120 (see FIG. 4) may include the first semiconductor layer SEL1, the first gate conductive layer GCDL1, and the second gate conductive layer GCDL2.

The first semiconductor layer SEL1 may include the channel portion CH5, the first electrode portion E15, and the second electrode portion E25 of the fifth transistor T5, and the channel portion CH6, the first electrode portion E16 and E16′, and the second electrode portion E26 of the fifth transistor T6.

The first gate conductive layer GCDL1 may include the gate electrode G5 of the fifth transistor T5, the gate electrode G6 of the sixth transistor T6, the first capacitor electrode CAE1, the power main line VDMNL, the scan write line GWL, the first emission control line ECL1, and the second emission control line ECL2.

The gate electrode G5 of the fifth transistor T5 may be a part of the first emission control line ECL1.

The gate electrode G6 of the sixth transistor T6 may be a part of the second emission control line ECL2.

The first capacitor electrode CAE1 may overlap the electrode extension E16′ connected to the first electrode E16 of the sixth transistor T6.

The second gate conductive layer GCDL2 may include the second capacitor electrode CAE2, a reference voltage main line VRMNL, and a first initialization voltage main line VIMNL1.

The second capacitor electrode CAE2 may overlap the first capacitor electrode CAE1.

In an embodiment, each of the power main line VDMNL, the scan write line GWL, the first emission control line ECL1, the second emission control line ECL2, the reference voltage main line VRMNL, and the first initialization voltage main line VIMNL1 may extend in the first direction DR1.

The first power line VDL that transmits the first power ELVDD (see FIGS. 6 and 7) may include the power main line VDMNL that is located in the first gate conductive layer GCDL1 and extends in the first direction DR1.

The reference voltage line VRL that transmits the reference voltage VREF (see FIGS. 6 and 7) may include the reference voltage main line VRMNL that is located in the second gate conductive layer GCDL2 and extends in the first direction DR1.

In an embodiment, the initialization voltage line VIL may include the first initialization voltage line VIL1 that transmits the first initialization voltage VINT1 (see FIG. 6), and the second initialization voltage line VIL2 that transmits the second initialization voltage VINT2 (see FIG. 7).

The first initialization voltage line VIL1 may include the first initialization voltage main line VIMNL1 that is located in the second gate conductive layer GCDL2 and extends in the first direction DR1.

The first initialization voltage main line VIMNL1 may be located adjacent to a boundary between two light emitting pixel drivers EPD that are adjacent to each other in the second direction DR2.

For example, one first initialization voltage main line VIMNL1 may be located adjacent to a boundary between one first light emitting pixel driver EPD1 and one third light emitting pixel driver EPD3 that are adjacent to each other in the second direction DR2.

One first initialization voltage main line VIMNL1 may also be located adjacent to a boundary between two second light emitting pixel drivers EPD2 that are adjacent to each other in the second direction DR2 and are adjacent to one first light emitting pixel driver EPD1 and one third light emitting pixel driver EPD3 in the first direction DR1, respectively.

According to an embodiment, the reset voltage main line VRMNL may be spaced apart from the first initialization voltage main line VIMNL1 (e.g., in a direction opposite to the second direction DR2) and located adjacent to a boundary between two other light emitting pixel drivers EPD adjacent to each other in the second direction DR2.

The reset voltage main line VRMNL and the first initialization voltage main line VIMNL1 may be arranged alternately in the second direction DR2.

For example, one side (e.g., a first side) of one of the two light emitting pixel drivers EPD adjacent to each other in the second direction DR2 may intersect one reset voltage main line VRMNL, and the other side (e.g., an opposite second side) may intersect one first initialization voltage main line VIMNL1.

In addition, one side (e.g., a first side) of the other of the two light emitting pixel drivers EPD adjacent to each other in the second direction DR2 may be adjacent to one first initialization voltage main line VIMNL1, and the other side (e.g., an opposite second side) may intersect another reset voltage main line VRMNL.

In this way, the number of the reset voltage main lines VRMNL arranged in the display area DA and the number of the first initialization voltage main lines VIMNL1 arranged in the display area DA may each be reduced to half the number of the pixel columns. Here, each of the pixel columns includes the light emitting pixel drivers EPD arranged side by side in the second direction.

Therefore, the width occupied by the reset voltage main line VRMNL and the first initialization voltage main line VIMNL1 in the display area DA may be reduced, which may be advantageous for achieving high resolution of the display device 100.

Referring to FIG. 14, in an embodiment each of the light emitting pixel drivers EPD may include the first, second, third, and fourth transistors T1, T2, T3, and T4, each of which is provided as an N-type MOSFET.

The circuit layer 120 (see FIG. 4) may further include the second semiconductor layer SEL2 and the third gate conductive layer GCDL3.

In an embodiment, the second semiconductor layer SEL2 may include the channel portions CH1, CH2, CH3, and CH4, the first electrode portions E11, E12, E13, and E14, and the second electrode portions E21, E22, E23, and E24 of the first, second, third and fourth transistors T1, T2, T3, and T4, respectively.

The third gate conductive layer GCDL3 may include the respective gate electrodes G1, G2, G3, and G4 of the first, second, third, and fourth transistors T1, T2, T3, and T4, the reset control line GRL, and the bias control line GBL.

The gate electrode G3 of the third transistor T3 may be a part of the reset control line GRL.

The gate electrode G4 of the fourth transistor T4 may be a part of the bias control line GBL.

Each of the reset control line GRL and the bias control line GBL may extend in the first direction DR1.

The bias control line GBL may be located adjacent to the first initialization voltage main line VIMNL1 in the second direction DR2.

The reset control line GRL may be located adjacent to the reset voltage main line VRMNL in the second direction DR2.

The bias control line GBL and the reset control line GRL may be arranged alternately in the second direction DR2.

For example, one side (e.g., a first side in the second direction DR2) of one of the two light emitting pixel drivers EPD adjacent to each other in the second direction DR2 may intersect one reset control line GRL, and the other side (e.g., an opposite second side in the second direction DR2) may intersect one bias control line GBL.

One side (e.g., a first side in the second direction DR2) of the other of the two light emitting pixel drivers EPD adjacent to each other in the second direction DR2 may be adjacent to one bias control line GBL, and the other side (e.g., an opposite second side in the second direction DR2) may intersect another reset control line GRL.

In this way, the number of the reset control lines GRL arranged in the display area DA and the number of the bias control lines GBL arranged in the display area DA may each be reduced to half the number of the pixel columns.

Therefore, the width occupied by the reset control line GRL and the bias control line GBL in the display area DA may be reduced, which may be advantageous for achieving high resolution of the display device 100.

Referring to FIGS. 15 and 16, the circuit layer 120 (see FIG. 4) of the display device 100 according to an embodiment may further include the first source-drain conductive layer SDCDL1 and the second source-drain conductive layer SDCDL2.

As illustrated in FIG. 15, in an embodiment the first source-drain conductive layer SDCDL1 may include the first node connection electrode NCE1, the second node connection electrode NCE2, a third node connection electrode NCE3, a first auxiliary connection electrode ACE1, a second auxiliary connection electrode ACE2, a third auxiliary connection electrode ACE3, a fourth auxiliary connection electrode ACE4, the data connection electrode DCE, the first anode connection electrode ANCE1, the power additional line VDAL, and a second initialization voltage main line VIMNL2.

In an embodiment, the first node connection electrode NCE1 may be electrically connected to the gate electrode G1 (see FIG. 14) of the first transistor T1 (see FIG. 14) through the first node connection hole NCH1, electrically connected to the first capacitor electrode CAE1 (FIG. 13) through the second node connection hole NCH2, and electrically connected to the second electrode portion E22 (see FIG. 14) of the second transistor T2 (see FIG. 14) through the third node connection hole NCH3.

The second node connection electrode NCE2 may be electrically connected to the second electrode portion E21 (see FIG. 14) of the first transistor T1 (see FIG. 14) through the fourth node connection hole NCH4, electrically connected to the second capacitor electrode CAE2 (see FIG. 13) through the fifth node connection hole NCH5, and electrically connected to the first electrode portion E16 (see FIG. 13) of the sixth transistor T6 (see FIG. 13) through the sixth node connection hole NCH6.

Through the first auxiliary connection electrode ACE1, the gate electrode G2 (see FIG. 14) of the second transistor T2 (see FIG. 14) may be electrically connected to the scan write line GWL (see FIG. 13).

Through the second auxiliary connection electrode ACE2, the first electrode portion E13 (see FIG. 14) of the third transistor T3 (see FIG. 14) may be electrically connected to the reference voltage main line VRMNL.

Through the third auxiliary connection electrode ACE3, the first electrode portion E11 (see FIG. 14) of the first transistor T1 (see FIG. 14) may be electrically connected to the second electrode portion E25 (see FIG. 13) of the fifth transistor T5 (see FIG. 13).

Through the fourth auxiliary connection electrode ACE4, the first electrode portion E14 (see FIG. 14) of the fourth transistor T4 (see FIG. 14) of the third light emitting pixel driver EPD3 may be electrically connected to the first initialization voltage main line VIMNL1.

The data connection electrode DCE may be electrically connected to the first electrode portion E12 (see FIG. 14) of the second transistor T2 (see FIG. 14).

The first anode connection electrode ANCE1 may be electrically connected to the second electrode portion E26 (see FIG. 13) of the sixth transistor T6 (see FIG. 13) through the first anode connection hole ANCH1.

The first anode connection electrode ANCE1 may be electrically connected to the second electrode portion E24 (see FIG. 14) of the fourth transistor T4 (see FIG. 14) through an anode additional connection hole ANACH.

Each of the power additional line VDAL and the second initialization voltage main line VIMNL2 may extend in the first direction DR1.

The power additional line VDAL may be adjacent to the power main line VDMNL in the second direction DR2, and may overlap the power main line VDMNL in the third direction DR3.

The second initialization voltage line VIL2 of the initialization voltage line VIL, which transmits the second initialization voltage VINT2 (see FIG. 7), may include the second initialization voltage main line VIMNL2 that is located in the first source-drain conductive layer SDCDL1 and extends in the first direction DR1.

The first electrode portion E14 (see FIG. 14) of the fourth transistor T4 (see FIG. 14) of the second light emitting pixel driver EPD2 may be electrically connected to the second initialization voltage main line VIMNL2.

As an example, when the parasitic capacitance of the light emitting element LE of the first emission area EA1 (see FIG. 5) corresponds to the second initialization voltage VINT2 (see FIG. 7), the first electrode portion E14 (see FIG. 14) of the fourth transistor T4 (see FIG. 14) of the first light emitting pixel driver EPD1 may also be electrically connected to the second initialization voltage main line VIMNL2, similarly to the second light emitting pixel driver EPD2.

As another example, when the parasitic capacitance of the light emitting element LE of the first emission area EA1 (see FIG. 5) corresponds to the first initialization voltage VINT1 (see FIG. 6), the first electrode portion E14 (see FIG. 14) of the fourth transistor T4 (see FIG. 14) of the first light emitting pixel driver EPD1 may be electrically connected to the first initialization voltage main line VIMNL1 through the fourth auxiliary connection electrode ACE4, similarly to the third light emitting pixel driver EPD3.

The second initialization voltage main line VIMNL2 may be located adjacent to a boundary between two light emitting pixel drivers EPD that are adjacent to each other in the second direction DR2.

For example, one second initialization voltage main line VIMNL2 may be located adjacent to a boundary between one first light emitting pixel driver EPD1 and one third light emitting pixel driver EPD3 that are adjacent to each other in the second direction DR2.

One second initialization voltage main line VIMNL2 may also be located adjacent to a boundary between two second light emitting pixel drivers EPD2 that are adjacent to each other in the second direction DR2 and are adjacent to one first light emitting pixel driver EPD1 and one third light emitting pixel driver EPD3 in the first direction DR1, respectively.

According to an embodiment, the first initialization voltage main line VIMNL1, the second initialization voltage main line VIMNL2, and the bias control line GBL may be arranged adjacent to each other in the second direction DR2 and may be arranged adjacent to a boundary between two light emitting pixel drivers EPD that are adjacent to each other in the second direction DR2.

By way of example, as illustrated in FIG. 15, the bias control line GBL may overlap (e.g., in a plan view) the boundary between the two light emitting pixel drivers EPD adjacent to each other in the second direction DR2, the first initialization voltage main line VIMNL1 may be located adjacent to the bias control line GBL on one side (e.g., a first side, such as an upper side in FIG. 15) in the second direction DR2, and the second initialization voltage main line VIMNL2 may be located adjacent to the bias control line GBL on the other side (e.g., an opposite second side, such as a lower side in FIG. 15) in the second direction DR2.

In this embodiment, one of the two light-emitting pixel drivers EPD that are adjacent to each other in the second direction DR2 may intersect the first initialization voltage main line VIMNL1, and the other may intersect the second initialization voltage main line VIMNL2.

In this way, since the bias control line GBL may be located between the first initialization voltage main line VIMNL1 and the second initialization voltage main line VIMNL2 that transmit a constant voltage in the second direction DR2, distortion of the bias control signal GB (see FIGS. 6 and 7) through the bias control line GBL may be reduced.

Accordingly, since the malfunction of the fourth transistor T4 (see FIGS. 6 and 7) may be reduced, the display quality of the display device 100 may be increased.

As illustrated in FIG. 16, the second source-drain conductive layer SDCDL2 may include the second anode connection electrode ANCE2, the data line DL, the second auxiliary line ASL2, the power sub-line VDSBL, and the reference voltage sub-line VRSBL.

In an embodiment, the second anode connection electrode ANCE2 may be electrically connected to the first anode connection electrode ANCE1 through the second anode connection hole ANCH2.

The anode electrode 131 (see FIG. 8) of the light emitting element LE (see FIG. 8) may be electrically connected to the second anode connection electrode ANCE2 through the third anode connection hole ANCH3.

Each of the data line DL, the second auxiliary line ASL2, the power sub-line VDSBL, and the reference voltage sub-line VRSBL may extend in the second direction DR2.

The data line DL may be electrically connected to the data connection electrode DCE.

The second auxiliary line ASL2 may be adjacent to the data line DL (e.g., in the first direction DR1).

According to an embodiment, as illustrated in FIGS. 13 and 14, in the first light emitting pixel driver EPD1 and the third light emitting pixel driver EPD3 that are adjacent to each other in the second direction DR2, the first semiconductor layer SEL1 of the first light emitting pixel driver EPD1 may be symmetrically arranged with the first semiconductor layer SEL1 of the third light emitting pixel driver EPD3 with respect to the boundary between the first light emitting pixel driver EPD1 and the third light emitting pixel driver EPD3.

Additionally, in the two second light emitting pixel drivers EPD2 that are adjacent to each other in the second direction DR2, the first semiconductor layer SEL1 of one second light emitting pixel driver EPD2 may be symmetrical with the first semiconductor layer SEL1 of the other second light emitting pixel driver EPD2 based on the boundary between the two second light emitting pixel drivers EPD2.

According to an embodiment, as illustrated in FIG. 14, in the first light emitting pixel driver EPD1 and the third light emitting pixel driver EPD3 that are adjacent to each other in the second direction DR2, the second semiconductor layer SEL2 of the first light emitting pixel driver EPD1 may be symmetrically arranged with the second semiconductor layer SEL2 of the third light emitting pixel driver EPD3 with respect to the boundary between the first light emitting pixel driver EPD1 and the third light emitting pixel driver EPD3.

In the two second light emitting pixel drivers EPD2 that are adjacent to each other in the second direction DR2, the second semiconductor layer SEL2 of one second light emitting pixel driver EPD2 may be symmetrically arranged with the second semiconductor layer SEL2 of the other second light emitting pixel driver EPD2 with respect to the boundary between the two second light emitting pixel drivers EPD2.

According to an embodiment, as illustrated in FIGS. 13, 14, 15, and 16, in the first light emitting pixel driver EPD1 and the third light emitting pixel driver EPD3 that are adjacent to each other in the second direction DR2, the first gate conductive layer GCDL1, the second gate conductive layer GCDL2, the third gate conductive layer GCDL3, the first source-drain conductive layer SDCDL1, and the second source-drain conductive layer SDCDL2 of the first light emitting pixel driver EPD1 may be symmetrically arranged with the first gate conductive layer GCDL1, the second gate conductive layer GCDL2, the third gate conductive layer GCDL3, the first source-drain conductive layer SDCDL1, and the second source-drain conductive layer SDCDL2 of the third light emitting pixel driver EPD3, respectively, with respect to the boundary between the first light emitting pixel driver EPD1 and the third light emitting pixel driver EPD3.

In the two second light emitting pixel drivers EPD2 that are adjacent to each other in the second direction DR2, the first gate conductive layer GCDL1, the second gate conductive layer GCDL2, the third gate conductive layer GCDL3, the first source-drain conductive layer SDCDL1, and the second source-drain conductive layer SDCDL2 of one second light emitting pixel driver EPD2 may be symmetrically arranged with the first gate conductive layer GCDL1, the second gate conductive layer GCDL2, the third gate conductive layer GCDL3, the first source-drain conductive layer SDCDL1, and the second source-drain conductive layer SDCDL2 of the other second light emitting pixel driver EPD2, respectively, with respect to the boundary between the two second light emitting pixel drivers EPD2.

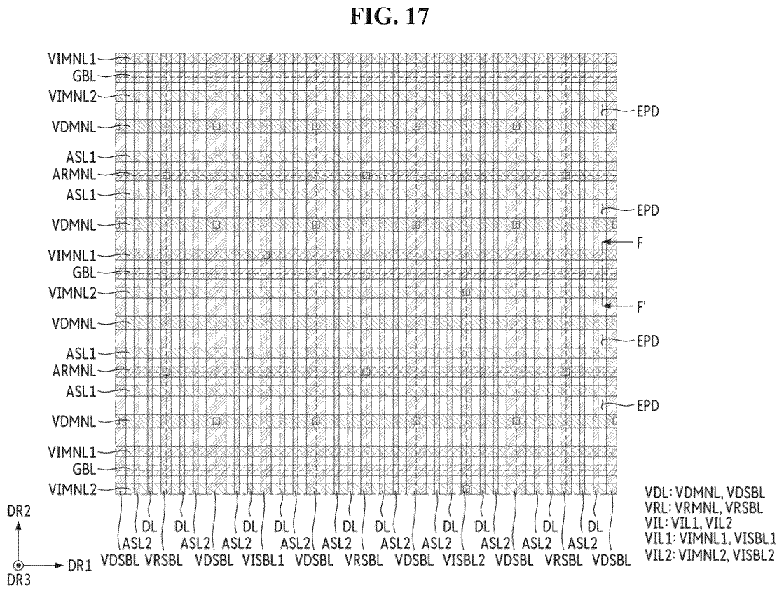

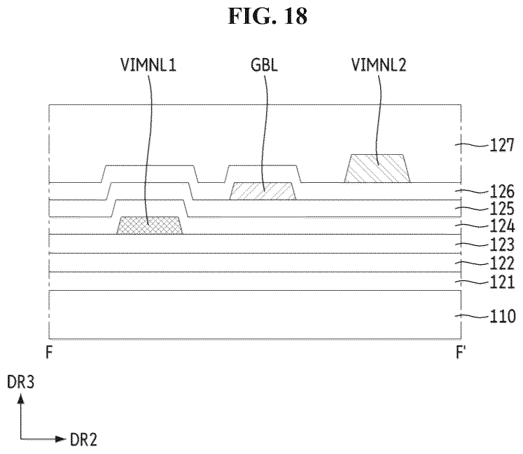

FIG. 17 is a plan view showing a first power line, a reference voltage line, and an initialization voltage line according to an embodiment. FIG. 18 is a cross-sectional view taken along line F-F′ of FIG. 17.

As shown in FIG. 17, according to an embodiment, the first power line VDL may include the power main line VDMNL that is located in the first gate conductive layer GCDL1 (see FIG. 13) and extends in the first direction DR1, and the power sub-line VDSBL that is located in the second source-drain conductive layer SDCDL2 (see FIG. 16), extends in the second direction DR2, and is electrically connected to the power main line VDMNL.

In this way, the first power line VDL that transmits the first power ELVDD (see FIGS. 6 and 7) is arranged in a mesh form (e.g., in a plan view) including the power main line VDMNL extending in the first direction DR1 and the power sub-line VDSBL extending in the second direction DR2, so that the first power ELVDD (see FIGS. 6 and 7) may be evenly transmitted to the display area DA with relatively low resistance.

According to an embodiment, the first power line VDL may further include the power additional line VDAL (see FIG. 15) that is located in the first source-drain conductive layer SDCDL1 (see FIG. 15), extends in the first direction DR1, and is electrically connected to the power main line VDMNL.

In this way, the resistance of the first power line VDL may be further reduced by the power additional line VDAL (see FIG. 15).

According to an embodiment, the reference voltage line VRL may include the reference voltage main line VRMNL that is located in the second gate conductive layer GCDL2 (see FIG. 13) and extends in the first direction DR1, and the reference voltage sub-line VRSBL that is located in the second source-drain conductive layer SDCDL2 (see FIG. 16), extends in the second direction DR2, and is electrically connected to the reference voltage main line VRMNL.

In this way, the reference voltage line VRL that transmits the reference voltage VREF (see FIGS. 6 and 7) is arranged in a mesh form including the reference voltage main line VRMNL extending in the first direction DR1 and the reference voltage sub-line VRSBL extending in the second direction DR2, so that the reference voltage VREF (see FIGS. 6 and 7) may be evenly transmitted to the display area DA with relatively low resistance.

According to an embodiment, the initialization voltage line VIL that transmits the initialization voltage VINT (see FIGS. 6 and 7) for initializing the light emitting elements LE (see FIG. 8) may include the first initialization voltage line VIL1 that transmits the first initialization voltage VINT1 (see FIG. 6) for initializing the light emitting elements LE of the third emission areas EA3 (see FIG. 5), and the second initialization voltage line VIL2 that transmits the second initialization voltage VINT2 (see FIG. 7) for initializing the light emitting elements LE of the second emission areas EA2 (see FIG. 5).

The first initialization voltage VINT1 (see FIG. 6) and the second initialization voltage VINT2 (see FIG. 7) have different voltage levels from each other. Therefore, even if some light emitting elements LE and some other light emitting elements LE have different parasitic capacitances, they may be respectively initialized to the initialization voltages of the voltage levels corresponding to the respective parasitic capacitances.

According to an embodiment, the first initialization voltage line VIL1 may include the first initialization voltage main line VIMNL1 that is located in the second gate conductive layer GCDL2 (see FIG. 13) and extends in the first direction DR1, and the first initialization voltage sub-line VISBL1 that is located in the second source-drain conductive layer SDCDL2 (see FIG. 16), extends in the second direction DR2, and is electrically connected to the first initialization voltage main line VIMNL1.

Likewise, the second initialization voltage line VIL2 may include the second initialization voltage main line VIMNL2 that is located in the second gate conductive layer GCDL2 (see FIG. 13) and extends in the first direction DR1, and the second initialization voltage sub-line VISBL2 that is located in the second source-drain conductive layer SDCDL2 (see FIG. 16), extends in the second direction DR2, and is electrically connected to the second initialization voltage main line VIMNL2.

In this way, each of the first initialization voltage line VIL1 that transmits the first initialization voltage VINT1 (see FIG. 6) and the second initialization voltage line VIL2 that transmits the second initialization voltage VINT2 (see FIG. 7) is arranged in a mesh form, so that each of the first initialization voltage VINT1 (see FIG. 6) and the second initialization voltage VINT2 (see FIG. 7) may be evenly transmitted to the display area DA with relatively low resistance.

According to an embodiment, each of the power sub-line VDSBL, the reference voltage sub-line VRSBL, the first initialization voltage sub-line VISBL1, and the second initialization voltage sub-line VISBL2 may be arranged adjacent to a boundary between two light emitting pixel drivers EPD that are adjacent in the first direction DR1.

In this way, each of the first power line VDL, the reference voltage line VRL, the first initialization voltage line VIL1, and the second initialization voltage line VIL2 may be arranged in a mesh form, while the width allocated to the arrangement of the power sub-line VDSBL, the reference voltage sub-line VRSBL, the first initialization voltage sub-line VISBL1, and the second initialization voltage sub-line VISBL2 in the display area DA may be reduced, which may be advantageous for achieving high resolution of the display device 100.

For example, as illustrated in FIG. 17, the power sub-line VDSBL may be arranged alternately (e.g., along the first direction DR1) with the reference voltage sub-line VRSBL, the first initialization voltage sub-line VISBL1, and the second initialization voltage sub-line VISBL2.

The reference voltage sub-line VRSBL may be arranged alternately with the first initialization voltage sub-line VISBL1 and the second initialization voltage sub-line VISBL2 (e.g., along the first direction DR1).

The first initialization voltage sub-line VISBL1 and the second initialization voltage sub-line VISBL2 may be arranged alternately with each other (e.g., along the first direction DR1).

For example, in an embodiment the power sub-line VDSBL, the reference voltage sub-line VRSBL, the power sub-line VDSBL, the first initialization voltage sub-line VISBL1, the power sub-line VDSBL, the reference voltage sub-line VRSBL, the power sub-line VDSBL, the second initialization voltage sub-line VISBL2, the power sub-line VDSBL, and the reference voltage sub-line VRSBL may be repeatedly arranged in the first direction DR1 in sequence.

In this way, in the order of the first power ELVDD (see FIGS. 6 and 7), the reference voltage VREF (see FIGS. 6 and 7), and the initialization voltage VINT (see FIGS. 6 and 7), the respective voltage levels may be stably maintained throughout the display area DA.

The data line DL and the second auxiliary line ASL2 may intersect each of the light emitting pixel drivers EPD.

According to an embodiment, the power main line VDMNL extending in the first direction DR1 may intersect each of the light emitting pixel drivers EPD.

According to an embodiment, the bias control line GBL, the first initialization voltage main line VIMNL1, and the second initialization voltage main line VIMNL2 and may be located adjacent to the boundary between the two light emitting pixel drivers EPD adjacent to each other in the second direction DR2.

As illustrated in FIG. 18, the first initialization voltage main line VIMNL1 may be located in the second gate conductive layer GCDL2 (see FIG. 13) on the second gate insulating layer 123 (e.g., directly thereon in the third direction DR3), the bias control line GBL may be located in the third gate conductive layer GCDL3 (see FIG. 14) on the third gate insulating layer 125 (e.g., directly thereon in the third direction DR3), and the second initialization voltage main line VIMNL2 may be arranged in the first source-drain conductive layer SDCDL1 (see FIG. 15) on the second interlayer insulating layer 126 (e.g., directly thereon in the third direction DR3).

As illustrated in FIGS. 17 and 18, according to an embodiment, the bias control line GBL, the first initialization voltage main line VIMNL1, and the second initialization voltage main line VIMNL2 may be spaced apart from each other (e.g., completely spaced apart from each other) in the second direction DR2.

For example, the first initialization voltage main line VIMNL1 may be adjacent to the bias control line GBL on one side in the second direction DR2, and the second initialization voltage main line VIMNL2 may be adjacent to the bias control line GBL on the other side in the second direction DR2. For example, as shown in an embodiment of FIG. 18, the first initialization voltage main line VIMNL1 may be adjacent to the bias control line GBL on the left side in the second direction DR2, and the second initialization voltage main line VIMNL2 may be adjacent to the bias control line GBL on right side in the second direction DR2. However, embodiments of the present disclosure are not necessarily limited thereto. In an embodiment, the first initialization voltage main line VIMNL1, the second initialization voltage main line VIMNL2 and the bias control line GBL may not overlap each other in the third direction DR3.

The reference voltage main line VRMNL may be spaced apart from the bias control line GBL, the first initialization voltage main line VIMNL1, and the second initialization voltage main line VIMNL2, and may be located adjacent to the boundary between the two light emitting pixel drivers EPD adjacent to each other in the second direction DR2.

In this way, the width allocated to the arrangement of the reference voltage main line VRMNL, the bias control line GBL, the first initialization voltage main line VIMNL1, and the second initialization voltage main line VIMNL2 in the display area DA may be reduced, which may be advantageous for achieving high resolution of the display device 100.

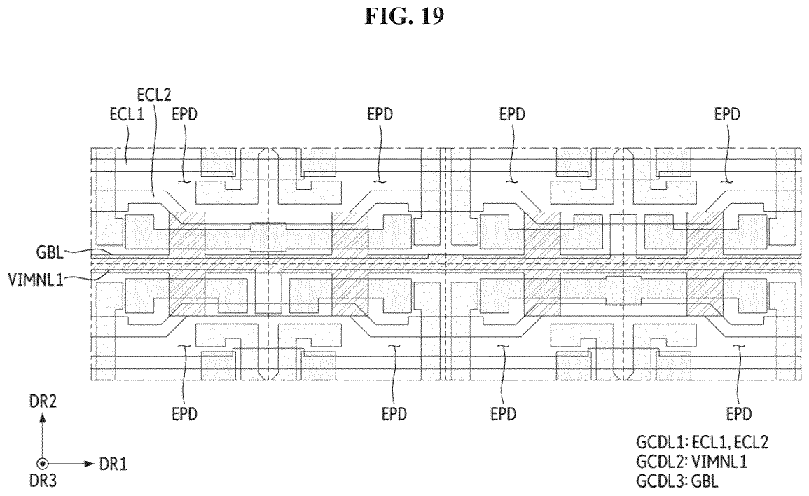

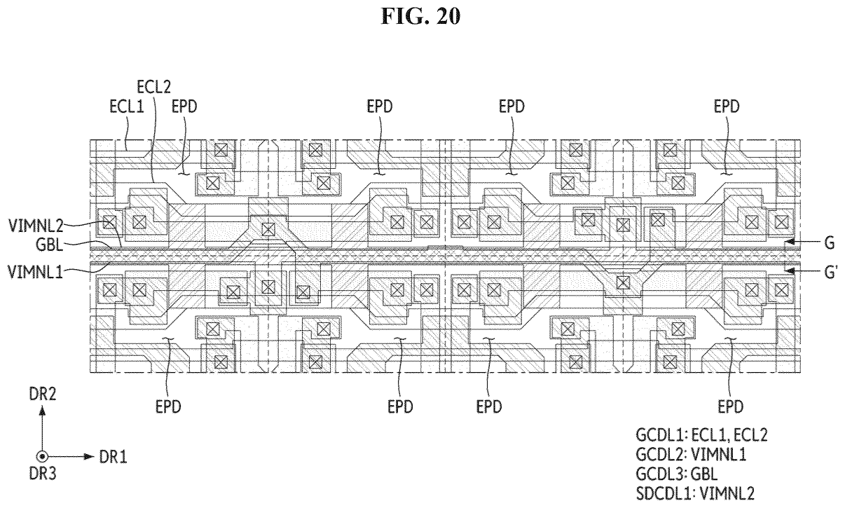

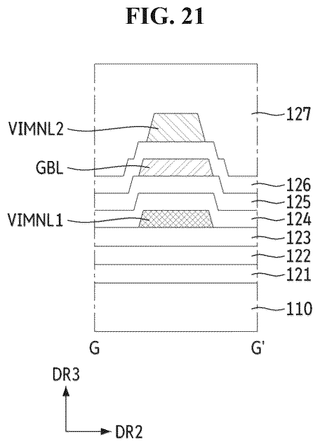

FIGS. 19 and 20 are plan views showing a first initialization voltage main line, a bias control line, and a second initialization voltage main line according to an embodiment. FIG. 21 is a cross-sectional view taken along line G-G′ of FIG. 20.

The display device 100 of an embodiment shown in FIGS. 19, 20, and 21 is substantially identical to the display device 100 of an embodiment shown in FIGS. 3 to 18, except that the bias control line GBL, the first initialization voltage main line VIMNL1, and the second initialization voltage main line VIMNL2 are not spaced apart from each other in the second direction DR2 but overlap each other in the third direction DR3, which is the thickness direction of the substrate 110 (see IG. 4). Therefore, in the following, redundant descriptions will be omitted for economy of explanation.

In this way, since the bias control line GBL is interposed between the first initialization voltage main line VIMNL1 and the second initialization voltage main line VIMNL2 in the third direction DR3, distortion of the bias control signal GB (see FIGS. 6 and 7) through the bias control line GBL may be further reduced. For example, in an embodiment, the bias control line GBL and the first initialization voltage main line VIMNL1 may have a substantially same length as each other in the second direction DR2 and may completely overlap each other in the third direction DR3. The second initialization voltage main line VIMNL2 may have a smaller length in the second direction DR2 than the bias control line GBL and the first initialization voltage main line VIMNL1 and an entirety of the second initialization voltage main line VIMNL2 may be overlapped by the first initialization voltage mainline VIMNL1 and the bias control line GBL in the third direction DR3.

In addition, the width occupied by the bias control line GBL, the first initialization voltage main line VIMNL1, and the second initialization voltage main line VIMNL2 in the display area DA may be further reduced, which may be more advantageous for achieving high resolution of the display device 100.

The display device 100 of each embodiment as described above may be applied to various electronic devices 10.

The electronic device 10 according to an embodiment may include the display device 100 described above.

Additionally, the electronic device 10 according to an embodiment may further include a module or device having other additional functions in addition to the display device 100.

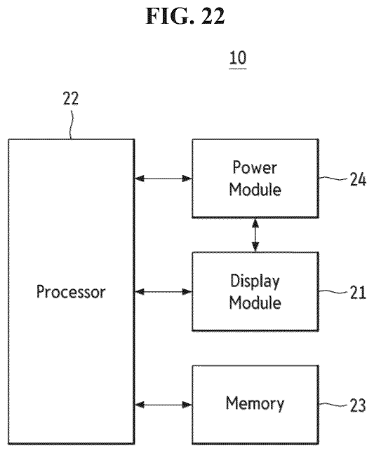

FIG. 22 is a block diagram of an electronic device according to an embodiment.

Referring to FIG. 22, the electronic device 10 according to an embodiment may include a display module 21, a processor 22, a memory 23, and a power module 24.

The display module 21 may include the display device 100 that displays an image.

The processor 22 may include at least one of a central processing unit (CPU), an application processor (AP), a graphic processing unit (GPU), a communication processor (CP), an image signal processor (ISP), or a controller.

The memory 15 may store data information required for the operation of the processor 22 or the display module 21. When the processor 22 executes an application stored in the memory 15, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power required for the operation of the electronic device 10.

At least one of the components of the electronic device 10 described above may be included in the display device according to embodiments described above. Further, some of individual modules functionally included in one module may be included in the display device and some others may be provided separately from the display device. For example, the display device may include the display module 21, and the processor 22, the memory 23, and the power module 24 may be provided in the form of other devices in the electronic device 10 other than the display device.

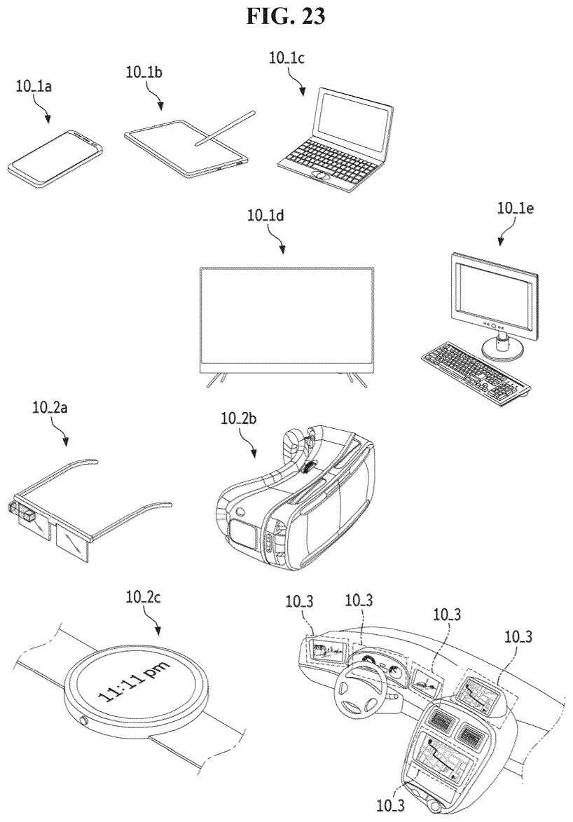

FIG. 23 is schematic views of electronic devices according to various embodiments.

Referring to FIG. 23, the electronic devices 10 according to embodiments may include not only an image display electronic device such as a smartphone 10_1a, a tablet PC 10_1b, a laptop 10_1c, a TV 10_1d, and a desk monitor 10_1e, but also a wearable electronic device such as smart glasses 10_2a, a head mounted display 10_2b, and a smart watch 10_2c, and a vehicle electronic device 10_3 such as a dashboard of a vehicle, a center fascia, a center information display (CID) of the dashboard, and a room mirror display. The electronic devices 10 may include various other small-sized, medium-sized and large-sized electronic devices.

However, the effects of embodiments of the present disclosure are not restricted to the one set forth herein.

What is claimed is:

1. A display device comprising:
a substrate comprising a display area including a plurality of emission areas arranged therein and a non-display area located around the display area;
a circuit layer located on the substrate; and
an element layer located on the circuit layer,
wherein the element layer comprises light emitting elements arranged in each of the plurality of emission areas,
the circuit layer comprises:
light emitting pixel drivers electrically connected to the light emitting elements and arranged in a first direction and a second direction intersecting the first direction; and
an initialization voltage line transmitting an initialization voltage to the light emitting pixel drivers,
the plurality of emission areas comprises first emission areas, second emission areas, and third emission areas that emit light of different wavelength bands from each other,
the light emitting pixel drivers comprise:
first light emitting pixel drivers electrically connected to the light emitting elements of the first emission areas;
second light emitting pixel drivers electrically connected to the light emitting elements of the second emission areas; and
third light emitting pixel drivers electrically connected to the light emitting elements of the third emission areas,
the initialization voltage line comprises:
a first initialization voltage line transmitting a first initialization voltage to the third light emitting pixel drivers; and
a second initialization voltage line transmitting a second initialization voltage having a different voltage level from the first initialization voltage to the second light emitting pixel drivers.

2. The display device of claim 1, wherein the circuit layer comprises:
a first semiconductor layer located on the substrate;
a first gate insulating layer covering the first semiconductor layer;
a first gate conductive layer located on the first gate insulating layer;
a second gate insulating layer covering the first gate conductive layer;
a second gate conductive layer located on the second gate insulating layer;
a first interlayer insulating layer covering the second gate conductive layer;
a second semiconductor layer located on the first interlayer insulating layer;
a third gate insulating layer covering the second semiconductor layer;
a third gate conductive layer located on the third gate insulating layer;
a second interlayer insulating layer covering the third gate conductive layer; and
a first source-drain conductive layer located on the second interlayer insulating layer,
the first initialization voltage line comprises a first initialization voltage main line located in the second gate conductive layer and extending in the first direction, and
the second initialization voltage line comprises a second initialization voltage main line located in the first source-drain conductive layer and extending in the first direction.

3. The display device of claim 2, wherein the circuit layer further comprises:
a bias control line transmitting a bias control signal to the light emitting pixel drivers, the bias control line extends in the first direction and is located in the third gate conductive layer, and
the first initialization voltage main line, the second initialization voltage main line, and the bias control line are located adjacent to each other in the second direction, and located adjacent to a boundary between two light emitting pixel drivers adjacent to each other in the second direction.

4. The display device of claim 3, wherein:
the first light emitting pixel drivers are electrically connected to the first initialization voltage line;
one first light emitting pixel driver and one third light emitting pixel driver adjacent to each other in the second direction are electrically connected to one first initialization voltage main line and one bias control line located adjacent to a boundary between the one first light emitting pixel driver and the one third light emitting pixel driver; and
two second light emitting pixel drivers adjacent to the one first light emitting pixel driver and the one third light emitting pixel driver in the first direction and adjacent to each other in the second direction are electrically connected to one second initialization voltage main line and the one bias control line located adjacent to a boundary between the two second light emitting pixel drivers.

5. The display device of claim 3, wherein:
the first light emitting pixel drivers are electrically connected to the second initialization voltage line;
two second light emitting pixel drivers adjacent to each other in the second direction and one first light emitting pixel driver adjacent to one of the two second light emitting pixel drivers in the first direction are electrically connected to one second initialization voltage main line and one bias control line located adjacent to a boundary between the two second light emitting pixel drivers; and
one third light emitting pixel driver adjacent to the other one of the two second light emitting pixel drivers in the first direction and adjacent to the one first light emitting pixel driver in the second direction is electrically connected to one first initialization voltage main line and the one bias control line located adjacent to a boundary between the one first light emitting pixel driver and the one third light emitting pixel driver.

6. The display device of claim 3, wherein:
the first initialization voltage main line is located adjacent to the bias control line on a first side in the second direction; and
the second initialization voltage line is located adjacent to the bias control line on an opposite second side in the second direction.

7. The display device of claim 3, wherein the first initialization voltage main line, the second initialization voltage main line, and the bias control line overlap each other in a third direction, that is a thickness direction of the substrate intersecting the first and second directions.

8. The display device of claim 3, wherein each of the light emitting pixel drivers comprises:
a first transistor;
a second transistor electrically connected between a data line transmitting a data signal and a gate electrode of the first transistor;
a third transistor electrically connected between a reference voltage line transmitting a reference voltage and the gate electrode of the first transistor;
a fourth transistor electrically connected between one of the light emitting elements and the initialization voltage line;
a fifth transistor electrically connected between a first power line transmitting a first power and a first electrode of the first transistor;
a sixth transistor electrically connected between the one light emitting element and a second electrode of the first transistor;
a first capacitor electrically connected between the gate electrode of the first transistor and the second electrode of the first transistor; and
a second capacitor electrically connected between the first power line and the second electrode of the first transistor,
wherein each of the first transistor, the second transistor, the third transistor, the fourth transistor, the fifth transistor, and the sixth transistor comprises a gate electrode, a channel portion overlapping the gate electrode, a first electrode portion connected to a first side of the channel portion, and a second electrode portion connected to an opposite second side of the channel portion,
the channel portion, the first electrode portion and the second electrode portion of each of the first transistor, the second transistor, the third transistor and the fourth transistor are located in the second semiconductor layer,
the channel portion, the first electrode portion and the second electrode portion of each of the fifth transistor and the sixth transistor are located in the first semiconductor layer, and
the gate electrode of the fourth transistor is electrically connected to the bias control line.

9. The display device of claim 8, wherein the circuit layer further comprises:
a first planarization layer covering the first source-drain conductive layer;
a second source-drain conductive layer located on the first planarization layer; and
a second planarization layer covering the second source-drain conductive layer,
the data line extends in the second direction and is located in the second source-drain conductive layer,
the first initialization voltage line further comprises a first initialization voltage sub-line located in the second source-drain conductive layer, extending in the second direction and electrically connected to the first initialization voltage main line,
the second initialization voltage line further comprises a second initialization voltage sub-line located in the second source-drain conductive layer, extending in the second direction and electrically connected to the second initialization voltage main line,
the reference voltage line comprises:
a reference voltage main line located in the second gate conductive layer, extending in the first direction and spaced apart from the bias control line in the second direction; and
a reference voltage sub-line located in the second source-drain conductive layer, extending in the second direction and electrically connected to the reference voltage main line,
the first power line comprises:
a power main line located in the first gate conductive layer and extending in the first direction; and
a power sub-line located in the second source-drain conductive layer, extending in the second direction and electrically connected to the power main line,
one of the two light emitting pixel drivers is located adjacent to the reference voltage main line on a first side in the second direction, and
the other of the two light emitting pixel drivers is located adjacent to the reference voltage main line on an opposite second side in the second direction.

10. The display device of claim 9, wherein:
each of the power main line, the reference voltage sub-line, the first initialization voltage sub-line and the second initialization voltage sub-line is located adjacent to a boundary between two light emitting pixel drivers adjacent to each other in the first direction;
the power main line is arranged alternately with the reference voltage sub-line, the first initialization voltage sub-line, and the second initialization voltage sub-line;
the reference voltage sub-line is arranged alternately with the first initialization voltage sub-line and the second initialization voltage sub-line; and
the first initialization voltage sub-line and the second initialization voltage sub-line are arranged alternately with each other.

11. The display device of claim 3, further comprising a display driving circuit transmitting data signals of the light emitting pixel drivers,
wherein the circuit layer further comprises:
data lines located in the display area and transmitting the data signals to the light emitting pixel drivers;
data supply lines located in the non-display area and electrically connected between each of the data lines and the display driving circuit;
first auxiliary lines located in the display area and extending in the first direction; and
second auxiliary lines located in the display area, extending in the second direction and adjacent to the data lines,
a bypass area of the display area comprises a bypass middle area, a first bypass side area parallel to the bypass middle area in the first direction and in direct contact with the non-display area, and a second bypass side area located between the bypass middle area and the first bypass side area in the first direction,
the data supply lines extend to the bypass middle area and the second bypass side area,
the data lines comprise a first data line located in the first bypass side area, and a second data line located in the second bypass side area,
the data lines and the second auxiliary lines are located on an insulating layer covering the first auxiliary lines,
the first auxiliary lines comprise a first bypass auxiliary line electrically connected to the first data line,
the second auxiliary lines comprise a second bypass auxiliary line adjacent to the second data line and electrically connected to the first bypass auxiliary line,
the data supply lines comprise a first data supply line transmitting a data signal of the first data line, and a second data supply line transmitting a data signal of the second data line,
the first data supply line is electrically connected to the first data line through the second bypass auxiliary line and the first bypass auxiliary line, and
the second data supply line is electrically connected directly to the second data line.

12. The display device of claim 1, wherein:
the first emission areas emit light of a first wavelength band;
the second emission areas emit light of a second wavelength band lower than the first wavelength band; and
the third emission areas emit light of a third wavelength band lower than the second wavelength band.

13. An electronic device comprising:
a display device displaying an image;
a memory storing an application;
a processor executing the application and transmitting an image data signal and an input control signal to the display device; and
a power module transmitting a power to the display device,
wherein the display device comprises:
a substrate comprising a display area including a plurality of emission areas arranged therein and a non-display area located around the display area;
a circuit layer located on the substrate; and
an element layer located on the circuit layer,
wherein the element layer comprises light emitting elements arranged in each of the plurality of emission areas,
the circuit layer comprises:
light emitting pixel drivers electrically connected to the light emitting elements and arranged in a first direction and a second direction intersecting the first direction; and
an initialization voltage line transmitting an initialization voltage to the light emitting pixel drivers,
the initialization voltage line comprises:
a first initialization voltage line transmitting a first initialization voltage to a first portion of the light emitting pixel drivers; and
a second initialization voltage line transmitting a second initialization voltage having a different voltage level from the first initialization voltage to a second portion of the light emitting pixel drivers not including the first portion, and
each of the light emitting pixel drivers comprises:
a first transistor;
a second transistor electrically connected between a data line transmitting a data signal and a gate electrode of the first transistor;
a third transistor electrically connected between a reference voltage line transmitting a reference voltage and the gate electrode of the first transistor;
a fourth transistor electrically connected between one of the light emitting elements and the initialization voltage line;
a fifth transistor electrically connected between a first power line transmitting a first power and a first electrode of the first transistor;
a sixth transistor electrically connected between the one light emitting element and a second electrode of the first transistor;
a first capacitor electrically connected between the gate electrode of the first transistor and the second electrode of the first transistor; and
a second capacitor electrically connected between the first power line and the second electrode of the first transistor.

14. The electronic device of claim 13, wherein the plurality of emission areas comprise:
first emission areas emitting light of a first wavelength band;
second emission areas emitting light of a second wavelength band lower than the first wavelength band; and
third emission areas emitting light of a third wavelength band lower than the second wavelength band,
the light emitting pixel drivers comprise:
first light emitting pixel drivers electrically connected to the light emitting elements of the first emission areas;
second light emitting pixel drivers electrically connected to the light emitting elements of the second emission areas; and
third light emitting pixel drivers electrically connected to the light emitting elements of the third emission areas,
wherein the second light emitting pixel drivers are electrically connected to the second initialization voltage line, and
the third light emitting pixel drivers are electrically connected to the first initialization voltage line.

15. The electronic device of claim 14, wherein the circuit layer comprises:
a first semiconductor layer located on the substrate;
a first gate insulating layer covering the first semiconductor layer;
a first gate conductive layer located on the first gate insulating layer;
a second gate insulating layer covering the first gate conductive layer;
a second gate conductive layer located on the second gate insulating layer;
a first interlayer insulating layer covering the second gate conductive layer;
a second semiconductor layer located on the first interlayer insulating layer;
a third gate insulating layer covering the second semiconductor layer;
a third gate conductive layer located on the third gate insulating layer;
a second interlayer insulating layer covering the third gate conductive layer; and
a first source-drain conductive layer located on the second interlayer insulating layer,
each of the first transistor, the second transistor, the third transistor, the fourth transistor, the fifth transistor, and the sixth transistor comprises a gate electrode, a channel portion overlapping the gate electrode, a first electrode portion connected to a first side of the channel portion, and a second electrode portion connected to an opposite second side of the channel portion,
the channel portion, the first electrode portion and the second electrode portion of each of the first transistor, the second transistor, the third transistor and the fourth transistor are located in the second semiconductor layer,
the channel portion, the first electrode portion and the second electrode portion of each of the fifth transistor and the sixth transistor are located in the first semiconductor layer, and
the gate electrode of the fourth transistor is electrically connected to a bias control line transmitting a bias control signal.

16. The electronic device of claim 15, wherein:
the bias control line extends in the first direction and is located in the third gate conductive layer,
the first initialization voltage line comprises a first initialization voltage main line located in the second gate conductive layer and extending in the first direction, and
the second initialization voltage line comprises a second initialization voltage main line located in the first source-drain conductive layer and extending in the first direction, and
the first initialization voltage main line, the second initialization voltage main line, and the bias control line are located adjacent to each other in the second direction, and located adjacent to a boundary between two light emitting pixel drivers adjacent to each other in the second direction.

17. The electronic device of claim 16, wherein:
the first light emitting pixel drivers are electrically connected to the first initialization voltage line;
one first light emitting pixel driver and one third light emitting pixel driver adjacent to each other in the second direction are electrically connected to one first initialization voltage main line and one bias control line located adjacent to a boundary between the one first light emitting pixel driver and the one third light emitting pixel driver; and
two second light emitting pixel drivers adjacent to the one first light emitting pixel driver and the one third light emitting pixel driver in the first direction and adjacent to each other in the second direction are electrically connected to one second initialization voltage main line and the one bias control line located adjacent to a boundary between the two second light emitting pixel drivers.

18. The electronic device of claim 16, wherein:
the first light emitting pixel drivers are electrically connected to the second initialization voltage line;
two second light emitting pixel drivers adjacent to each other in the second direction and one first light emitting pixel driver adjacent to one of the two second light emitting pixel drivers in the first direction are electrically connected to one second initialization voltage main line and one bias control line located adjacent to a boundary between the two second light emitting pixel drivers; and
one third light emitting pixel driver adjacent to the other one of the two second light emitting pixel drivers in the first direction and adjacent to the one first light emitting pixel driver in the second direction is electrically connected to one first initialization voltage main line and the one bias control line located adjacent to a boundary between the one first light emitting pixel driver and the one third light emitting pixel driver.

19. The electronic device of claim 16, wherein:
the first initialization voltage main line is located adjacent to the bias control line on a first side in the second direction; and
the second initialization voltage line is located adjacent to the bias control line on an opposite second side in the second direction.

20. The electronic device of claim 16, wherein the first initialization voltage main line, the second initialization voltage main line, and the bias control line overlap each other in a third direction that is a thickness direction of the substrate.
